(19) United States
(12) Patent Application Publication
(10) Pub. No.: US 2010/0329296 A1
(43) Pub. Date: Dec. 30, 2010

(54) METHOD OF MANUFACTURING INTEGRATED SEMICONDUCTOR LASER DEVICE, INTEGRATED SEMICONDUCTOR LASER DEVICE AND OPTICAL APPARATUS

(75) Inventors: Masayuki HATA, Takatsuki-shi (JP); Kunio TAKEUCHI, Joyo-shi (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi-shi (JP)

(21) Appl. No.: 12/728,703

(22) Filed: Mar. 22, 2010

(30) Foreign Application Priority Data
Jun. 30, 2009 (JP) 2009-155590

(51) Int. Cl. H01S 5/40; H01S 5/02; H01L 21/50

(52) U.S. Cl. 372/50.12; 438/28; 257/E21.499

(57) ABSTRACT

A method of manufacturing a semiconductor laser device includes steps of forming a third oblong substrate by bonding a first oblong substrate and a second oblong substrate, and dividing the third oblong substrate so that first side surfaces of the first semiconductor laser devices protrude sideward from positions formed with third side surfaces of the second semiconductor laser devices while the fourth side surfaces of the second semiconductor laser devices protrude sideward from positions formed with the second side surfaces of the first semiconductor laser devices, and the first electrodes are located on protruding regions of the first semiconductor laser devices.

### CROSS-REFERENCE TO RELATED APPLICATIONS

The priority application number JP2009-155590, Method of Manufacturing Semiconductor Laser Device and Semiconductor Laser Device, Jun. 30, 2009, Masayuki Hata et al, upon which this patent application is based is hereby incorporated by reference.

### BACKGROUND OF THE INVENTION

1. Field of the Invention

The present invention relates to a method of manufacturing an integrated semiconductor laser device, an integrated semiconductor laser device, and an optical apparatus, and more particularly, it relates to a method of manufacturing an integrated semiconductor laser device comprising a step of bonding a first semiconductor laser device and a second semiconductor laser device, an integrated semiconductor laser device and an optical apparatus.

2. Description of the Background Art

An integrated semiconductor laser apparatus formed by bonding a red semiconductor laser device and an infrared semiconductor laser device on a blue-violet semiconductor laser device is known in general, as disclosed in Japanese Patent Laying-Open No. 2005-317919, for example.

The aforementioned Japanese Patent Laying-Open No. 2005-317919 discloses the integrated semiconductor laser apparatus in which the red and infrared semiconductor laser devices formed by employing a GaAs substrate are bonded to the blue-violet semiconductor laser device formed by employing a GaN substrate. In a manufacturing process of the semiconductor laser apparatus, the red and infrared semiconductor laser devices which are separated from each other are formed on prescribed positions on a surface of the blue-violet semiconductor laser device wafer by removing an unnecessary portion of the red/infrared semiconductor laser device wafer bonded on the surface of the blue-violet semiconductor laser device wafer. Then, the wafers in this state are cleaved in the form of a bar (oblong), thereby forming cavity facets of the respective semiconductor laser devices.

In the aforementioned integrated semiconductor laser apparatus disclosed in Japanese Patent Laying-Open No. 2005-317919, however, the red and infrared semiconductor laser devices separated from each other are bonded to the prescribed positions of the blue-violet semiconductor laser device wafer by removing the unnecessary portion of the red/infrared semiconductor laser device after bonding the wafers in the manufacturing process, and hence a step of removing the unnecessary portion from the wafer is required, thereby disadvantageously reducing the yield.

### SUMMARY OF THE INVENTION

A method of manufacturing an integrated semiconductor laser device formed by bonding a first semiconductor laser device and a second semiconductor laser device according to a first aspect of the present invention comprises steps of forming a third oblong substrate by bonding a first oblong substrate formed with a plurality of the first semiconductor laser devices and a second oblong substrate formed with a plurality of the second semiconductor laser devices, and dividing the third oblong substrate so that first side surfaces of the first semiconductor laser devices having the first side surfaces and second side surfaces protrude from positions formed with third side surfaces of the second semiconductor laser devices having the third side surfaces and fourth side surfaces while the fourth side surfaces opposite to the third side surfaces protrude from the second side surfaces opposite to the first side surfaces, wherein cavities of the first and second semiconductor laser devices extend along the first direction, the first, second, third and fourth side surfaces extend along the first direction, the first oblong substrate is so formed that a plurality of the first semiconductor laser devices are aligned along a second direction perpendicular to the first direction in an in-plane direction of the first oblong substrates, and the second oblong substrate is so formed that a plurality of the second semiconductor laser devices are aligned along the second direction.

In the method of manufacturing an integrated semiconductor laser device according to the first aspect of the present invention, as hereinabove described, the semiconductor laser device in which the respective side surfaces of the first and second semiconductor laser devices are bonded on the positions deviated from each other along a prescribed direction can be formed simultaneously with division of the third oblong substrate by dividing the third oblong substrate so that the first side surfaces of the first semiconductor laser devices having the first and second side surfaces protrude sideward from the positions formed with the third side surfaces of the second semiconductor laser devices having the third and fourth side surfaces while the fourth side surfaces opposite to the third side surfaces protrude sideward from the positions formed with the second side surfaces opposite to the first side surfaces. Thus, the semiconductor laser device is formed by dividing the third oblong substrate without removing unnecessary portions of the wafer, and hence yield can be improved.

The method of manufacturing an integrated semiconductor laser device according to the first aspect comprises the step of forming the third oblong substrate by bonding the first oblong substrate formed with the plurality of first semiconductor laser devices and the second oblong substrate formed with the plurality of second semiconductor laser devices. In other words, for example, when the third oblong substrate constituted by the first and second oblong substrates is formed by cleaving the wafer where the wafer constituted by the second semiconductor laser devices is bonded to the wafer constituted by the first semiconductor laser devices, the cleavage guide grooves for the second semiconductor laser devices may simply be formed only on ends of the wafer formed with the second semiconductor laser devices, corresponding to the positions for cleaving the wafer formed with the first semiconductor laser devices. Thus, each of the wafers on the first and second semiconductor laser device can be cleaved on a desired position, and hence the third oblong substrate where the cavity facets of the first and second semiconductor laser devices are aligned on the same plane can be formed. Consequently, deviation of the cavity facets of the respective semiconductor laser devices in a cavity direction can be suppressed. Additionally, dissimilarly to a case where a plurality of second semiconductor laser devices previously divided in the form of chips are individually bonded on the surface of the first oblong substrate, as another method, the third oblong substrate may simply be formed by bonding the second oblong substrate extending in a prescribed direction to the first oblong substrate extending in a prescribed direction while the extensional directions of the first and second oblong substrate are made coincide with each other when the third oblong substrate is formed by bonding the previously formed first and the second oblong substrates. Also in this case, the third oblong substrate where the cavity facets of the first and second semiconductor laser devices are aligned on the same plane can be formed, and hence the cavity facets formed on the respective laser devices can be inhibited from deviating from each other.

In the aforementioned method of manufacturing an integrated semiconductor laser device according to the first aspect, the step of forming the third oblong substrate preferably includes a step of bonding a first semiconductor laser device substrate formed with a plurality of the first semiconductor laser devices and a second semiconductor laser device substrate formed with a plurality of the second semiconductor laser devices, a step of dividing the first and second semiconductor laser device substrates simultaneously in a state where the first and second semiconductor laser device substrates are bonded to each other. According to this structure, the wafer formed by bonding the first and second semiconductor laser device substrates to each other is divided along division lines formed on both of the first and second semiconductor laser device substrates, and hence the division surfaces formed on the oblong substrate can be linearly aligned. Thus, the cavity facets constituting the respective semiconductor laser devices can easily be inhibited from deviation in the cavity direction at a step prior to division into chips. The second semiconductor laser device substrate before division is continuous, and hence the division groove may simply be formed on a single portion of the second semiconductor laser device substrate. Thus, a step of forming the division grooves can be simplified.

In the aforementioned method of manufacturing an integrated semiconductor laser device according to the first aspect, the integrated semiconductor laser device is preferably so formed that a first surface of the first semiconductor laser device and the second semiconductor laser device are bonded to each other and a first protruding region on the first surface between the first and third side surface is exposed from the second semiconductor laser device, and the aforementioned method preferably further comprises a step of forming first electrodes on the first protruding regions in advance of the step of forming the third oblong substrate, wherein the first electrodes are exposed from the second semiconductor laser devices in the step of dividing the third oblong substrate. According to this structure, the first electrodes for bonding the metal wire can be exposed on the surfaces of the first protruding regions of the first semiconductor laser devices simultaneously with division of the oblong substrate. In other words, a step such as a step of exposing the first electrodes on the surfaces of the protruding regions on individual chips is not required after dividing the third oblong substrate, and hence the manufacturing process is not complicated and can be further simplified.

In the aforementioned method of manufacturing an integrated semiconductor laser device according to the first aspect, the first and second oblong substrates preferably have cavity facets, and the method preferably further comprises a step of forming protective films on the cavity facets of the third oblong substrate in advance of the step of dividing the third oblong substrate. According to this structure, the third oblong substrate is formed with the protective films (insulating films) on the cavity facets in a state where the wafer has a substantially uniform thickness. Thus, for example, a disadvantage, that the first electrodes are insulated by the protective films extending toward and covering the surfaces of the exposed first electrodes does not occur dissimilarly to a case where the first electrodes and the like on the first semiconductor laser device substrate side are exposed by removing portions between the second semiconductor laser devices of the second oblong substrate before forming the protective films, and hence the metal wires bonded after division into chips and the first electrodes can be reliably electrically connected (wire-bonded).

The aforementioned method of manufacturing an integrated semiconductor laser device according to the first aspect preferably further comprises steps of forming first division grooves for forming the first and second side surfaces on the first oblong substrate, and forming second division grooves for forming the third and fourth side surfaces on a surface on an opposite surface of the second oblong substrate to a second surface of the second oblong substrate, in advance of the step of dividing the third oblong substrate, wherein the second division grooves are formed on positions deviated from positions opposed to the first division grooves, and the second surface is bonded to the first oblong substrate. According to this structure, the second oblong substrate can be also divided on the positions formed with the second division grooves in response to division of the first oblong substrate on the first division grooves when dividing the wafer. Thus, the integrated semiconductor laser device chip in a state where the third and fourth side surfaces of the second semiconductor laser devices are arranged on the positions deviated from the positions formed with the first and second side surfaces of the first semiconductor laser devices can be easily formed while dividing the third oblong substrate into chips.

The aforementioned structure including the step of dividing the first and second semiconductor laser device substrates simultaneously preferably further comprises steps of preparing the first semiconductor laser device substrate by forming a plurality of the first semiconductor laser devices in a first period along the second direction, preparing the second semiconductor laser device substrate by forming a plurality of the second semiconductor laser devices in a second period along the second direction, and performing alignment in order to bond the first and second semiconductor laser device substrates each other, in advance of the step of bonding the first and second semiconductor laser device substrates, wherein the first period at a temperature in the performing alignment is larger than the second period at the aforementioned temperature in case where a thermal expansion coefficient of the first semiconductor laser device substrate is smaller than that of the second semiconductor laser device substrate. According to this structure, a waveguide interval of the first semiconductor laser device substrate and a waveguide interval of the second semiconductor laser device substrate can substantially coincide with each other along the second direction when bonding the first and second semiconductor laser device substrates under a temperature condition higher than the temperature in the performing alignment. Consequently, light-emitting points formed on the respective laser device substrates when forming the third oblong substrate by simultaneously dividing the first and second semiconductor laser device substrates can be inhibited from deviating from design positions, and hence a plurality of the integrated semiconductor laser device chips where the positional relation of the light-emitting points in the individual chips substantially coincides can be obtained.

In the aforementioned structure including the step of dividing the first and second semiconductor laser device substrates simultaneously, the method further comprises steps of performing alignment in order to bond the first and second semiconductor laser device substrates to each other in advance of the step of bonding the first and second semiconductor laser device substrates, wherein the step of preparing the first semiconductor laser device substrate includes a step of forming first alignment marks employed in the performing alignment on the first semiconductor laser device substrate in a third period along a third direction, the step of preparing the second semiconductor laser device substrate includes a step of forming second alignment marks employed in the performing alignment on the second semiconductor laser device substrate in a fourth period along the third direction, and the third period at a temperature in the performing alignment is equal to the fourth period at the aforementioned temperature. According to this structure, the first and second alignment marks formed at the same period can be easily overlap in the alignment step, and hence bonding of the first and second semiconductor laser device substrates can be more precisely performed.

In the aforementioned structure including the step of dividing the first and second semiconductor laser device substrates simultaneously further comprises steps of preparing the first semiconductor laser device substrate by forming a plurality of the first semiconductor laser devices in a fifth period along the first direction, preparing the second semiconductor laser device substrate by forming a plurality of the second semiconductor laser devices in a sixth period along the first direction, and performing alignment in order to bond the first and second semiconductor laser device substrates to each other, in advance of the step of bonding the first and second semiconductor laser device substrates, wherein the fifth period at a temperature in the performing alignment is larger than the sixth period at the aforementioned temperature in case where a thermal expansion coefficient of the first semiconductor laser device substrate is smaller than that of the second semiconductor laser device substrate. According to this structure, a formation interval of the adjacent cavities of a plurality of the first semiconductor laser devices can substantially coincide with a formation interval of the adjacent cavities of a plurality of the second semiconductor laser devices along the first direction when bonding the first and second semiconductor laser devices under the temperature condition higher than that in the performing alignment. Consequently, because the respective cavity lengths of the first and second semiconductor laser device substrates can substantially coincide with each other at a bonding temperature, the first and second semiconductor laser device substrates can be so bonded to each other that individual design positions of the cleavage planes of the first semiconductor laser device substrate substantially coincide with individual design positions of the cleavage planes of the second semiconductor laser device substrate. And hence the cleavage position of each of the laser devices can be inhibited from deviating from a design position.

In the aforementioned method of manufacturing an integrated semiconductor laser device according to the first aspect, the first oblong substrate preferably has a substrate made of a nitride-based semiconductor, and the second oblong substrate preferably has a substrate made of a GaAs-based semiconductor. Thus, the integrated semiconductor laser device chip suppressing deviation of the cavity facets in the cavity direction (first direction) can be easily obtained, although the nitride-based semiconductor (GaN) is a harder material than the GaAs-based semiconductor and has a property inferior in cleavability.

An integrated semiconductor laser device according to a second aspect of the present invention comprises a first semiconductor laser device formed with a first electrode on a first surface and having a first side surface and a second side surface opposite to the first side surface, a second semiconductor laser device having a second surface bonded to the first surface, a third side surface and a fourth side surface opposite to the third side surface, and a second electrode arranged on the first semiconductor laser device and connected to the second semiconductor laser device, wherein cavities of the first and second semiconductor laser devices extend along the first direction, the first, second, third and fourth side surfaces extend along the first direction, a first protruding region on the first surface is exposed between the first and third side surfaces from the second semiconductor laser device, and a second protruding region on the second surface is exposed between the second and fourth side surfaces from the first semiconductor laser device, and the second electrode is formed to extend from a portion between the second and first semiconductor laser devices to the first protruding region.

In the integrated semiconductor laser device according to the second aspect of the present invention, as hereinabove described, the first protruding region on the first surface is exposed between the first and third side surfaces from the second semiconductor laser device, and the second protruding region on the second surface is exposed between the second and fourth side surfaces from the first semiconductor laser device. In other words, dissimilarly to a case where the wafer is divided after the second semiconductor laser devices having a device width smaller in an inner direction of the device than the first and second side surfaces of the first semiconductor laser devices are formed on the surface of first semiconductor laser device by removing unnecessary portions from the second semiconductor laser device wafer where the wafer constituted by the plurality of first semiconductor laser devices and the wafer constituted by the plurality of second semiconductor laser devices are bonded to each other, for example, in the manufacturing process, the integrated semiconductor laser device where the respective side surfaces of the first and second semiconductor laser devices are bonded on the positions deviated from each other along a prescribed direction is formed, whereby the semiconductor laser device can be formed by dividing the wafer without removing unnecessary portions of the wafer. Thus, the yield of the integrated semiconductor laser device can be improved.

In the integrated semiconductor laser device according to the second aspect, the first protruding region on the first surface is exposed between the first and third side surfaces from the second semiconductor laser device, and a first metal wire is bonded to the portion of the first electrode located on the first protruding region. In other words, no step of etching from the second semiconductor laser device after bonding the wafers to expose the first electrode for connecting the first metal wire on the surface of the first semiconductor laser device may be separately performed in the manufacturing process, and hence the manufacturing process of the integrated semiconductor laser device can be simplified because of unnecessity of such a step.

In the integrated semiconductor laser device according to the second aspect, a second electrode is formed to extend from a portion between the second and first semiconductor laser devices to the first protruding region, whereby not only the first electrode but also the second electrode can be easily connected to the outside from the first protruding region.

In the aforementioned integrated semiconductor laser device according to the second aspect, a first metal wire is connected to a portion of the first electrode located on the first protruding region, and a second metal wire is connected to a portion of the second electrode located on the first protruding region. According to this structure, the second metal wire connected to the outside can be connected to the second electrode on the same side as the first metal wire, and hence the metal wires can be arranged to concentrate on the same side of the integrated semiconductor laser device.

In the aforementioned integrated semiconductor laser device according to the second aspect, the second electrode is preferably arranged to hold an insulating layer on the first semiconductor laser device, and the first and second electrodes are preferably arranged in a state of being insulated from each other. According to this structure, the first and second electrodes can be arranged to be adjacent by effectively utilizing the first protruding region, and hence the first protruding region can be inhibited from unnecessarily broadening in the width direction of the first semiconductor laser device.

In this case, a region connected with the first metal wire of the first electrode and a region connected with the second metal wire of the second electrode are preferably separated from each other in the first direction on the first protruding region. According to this structure, the wire bonding portion for bonding the metal wire to the first and second electrodes can be aligned in the first direction, and hence the width of the first protruding region can be reduced. Thus, the width of the integrated semiconductor laser device can be reduced.

In the aforementioned integrated semiconductor laser device according to the second aspect, the second semiconductor laser device is bonded to overlap on a waveguide of the first semiconductor laser device. According to this structure, the waveguide of the first semiconductor laser device does not expose from the second semiconductor laser device, and hence the integrated semiconductor laser device can be formed to bring the second semiconductor laser device close to the light-emitting point of the first semiconductor laser device.

In this case, the first electrode is preferably formed to extend from a portion between the first and second semiconductor laser devices to the first protruding region. According to this structure, the wire bonding portion of the first electrode can be arranged on a portion separated from the light-emitting point of the first semiconductor laser device, and hence an impact to the waveguide in bonding can be reduced and the metal wire can be easily bonded to the first electrode.

In the aforementioned structure where the second semiconductor laser device overlaps on the waveguide of the first semiconductor laser device, the waveguide of the second semiconductor laser device is preferably formed on a position overlapped with the first semiconductor laser device. According to this structure, the integrated semiconductor laser device where the light-emitting point of the first semiconductor laser device and the light-emitting point of the second semiconductor laser device overlapping on the first semiconductor laser device reliably approach each other can be easily obtained.

In this case, the waveguide of the first semiconductor laser device is preferably formed on the first protruding region. According to this structure, damage to the waveguide of the first semiconductor laser device in bonding the second semiconductor laser device to the first surface can be suppressed. Additionally, deterioration of electric characteristics of the first electrode side in bonding the second semiconductor laser device to the first surface can be suppressed.

In the aforementioned integrated semiconductor laser device according to the second aspect, a device width of the first semiconductor laser device from the first side surface to the second side surface is equal to a device width of the second semiconductor laser device from the third side surface to the fourth side surface. According to this structure, the individual integrated semiconductor laser device chips can be easily formed in a state where the width of the first protruding region along the direction orthogonal to the first direction is equal to the width of the second protruding region.

In the aforementioned integrated semiconductor laser device according to the second aspect, the first semiconductor laser device has a substrate made of a nitride-based semiconductor, and the second semiconductor laser device has a substrate made of a GaAs-based semiconductor. According to this structure, the integrated semiconductor laser device suppressing deviation of the cavity facets in the cavity direction can be easily obtained, although the nitride-based semiconductor (GaN) is a harder material than the GaAs-based semiconductor and has a property inferior in cleavability.

An optical apparatus according to a third aspect of the present invention comprises an integrated semiconductor laser device including a first semiconductor laser device formed with a first electrode on a first surface and having a first side surface and a second side surface opposite to the first side surface, a second semiconductor laser device having a second surface bonded to the first surface, a third side surface and a fourth side surface opposite to the third side surface, and a second electrode arranged on the first semiconductor laser device and connected to the second semiconductor laser device, and an optical system controlling light emitted from the integrated semiconductor laser device, wherein a first protruding region on the first surface is exposed between the first and third side surfaces from the second semiconductor laser device, a second protruding region on the second surface is exposed between the second and fourth side surfaces from the first semiconductor laser device, and the second electrode is formed to extend from a portion between the second and first semiconductor laser devices to the first protruding region, cavities of the first and second semiconductor laser devices extend along the first direction, and the first, second, third and fourth side surfaces extend along the first direction.

In the optical apparatus according to the third aspect of the present invention, as hereinabove described, the first protruding region on the first surface is exposed between the first and third side surfaces from the second semiconductor laser device, and the second protruding region on the second surface is exposed between the second and fourth side surfaces from the first semiconductor laser device. In other words, the integrated semiconductor laser device where the respective side surfaces of the first and second semiconductor laser devices are bonded on the positions deviated from each other along a prescribed direction is formed, whereby the semiconductor laser device can be formed by dividing the wafer without removing unnecessary portions of the wafer. Thus, the optical apparatus comprising the integrated semiconductor laser device where yield is improved can be obtained.

In the optical apparatus according to the third aspect, the first protruding region on the first surface is exposed between the first and third side surfaces from the second semiconductor laser device, and a first metal wire is bonded to a portion of the first electrode located on the first protruding region. In other words, no step of etching the second semiconductor laser device after bonding the wafers to expose the first electrode for bonding the first metal wire on the surface of the first semiconductor laser device, for example, may be separately performed in the manufacturing process, and hence the optical apparatus can be easily obtained by comprising the semiconductor laser device where the manufacturing process is simplified because of unnecessity of such a manufacturing process.

In the optical apparatus according to the third aspect, the second electrode is formed to extend from the portion between the second and first semiconductor laser devices to the first protruding region, whereby not only the first electrode but also the second electrode can be easily connected to the outside from the first protruding region of the first semiconductor device.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view showing a structure of a semiconductor laser device according to a first embodiment of the present invention;

FIG. 2 is a sectional view taken along the line 1000-1000 in FIG. 1;

FIG. 3 is a sectional view taken along the line 1100-1100 in FIG. 1;

FIG. 4 is a sectional view taken along the line 2000-2000 in FIG. 1;

FIG. 5 is a sectional view taken along the line 3000-3000 in FIG. 1;

FIG. 6 is a plan view showing a structure of the semiconductor laser device according to the first embodiment of the present invention;

FIGS. 7 to 15 are diagrams for illustrating a manufacturing process of the semiconductor laser device according to the first embodiment of the present invention;

FIG. 16 is a sectional view showing a structure of a semiconductor laser device according to a second embodiment of the present invention;

FIG. 17 is a plan view showing a structure of the semiconductor laser device according to the second embodiment of the present invention;

FIG. 18 is a plan view for illustrating a manufacturing process of the semiconductor laser device according to the second embodiment of the present invention;

FIG. 19 is a plan view showing a structure of a semiconductor laser device according to a third embodiment of the present invention;

FIG. 20 is a sectional view taken along the line 1500-1500 in FIG. 19;

FIG. 21 is a sectional view taken along the line 2500-2500 in FIG. 19;

FIG. 22 is a sectional view taken along the line 3500-3500 in FIG. 19;

FIG. 23 is a block diagram of an optical pickup having a build-in semiconductor laser apparatus mounted with a semiconductor laser device according to a fourth embodiment of the present invention;

FIG. 24 is an external perspective view showing a schematic structure of the semiconductor laser apparatus mounted with the semiconductor laser device according to the fourth embodiment of the present invention;

FIG. 25 is a front elevational view of a state where a lid body of a can package of the semiconductor laser apparatus mounted with the semiconductor laser device according to the fourth embodiment of the present invention is removed;

FIG. 26 is a block diagram of an optical disc apparatus comprising an optical pickup mounted with a semiconductor laser device according to a fifth embodiment of the present invention;

FIG. 27 is a front elevational view showing a structure of a semiconductor laser apparatus mounted with a semiconductor laser device according to a sixth embodiment of the present invention;

FIG. 28 is a block diagram of a projector mounted with a semiconductor laser device according to the sixth embodiment of the present invention;

FIG. 29 is a block diagram of a projector mounted with a semiconductor laser device according to a seventh embodiment of the present invention; and

FIG. 30 is a timing chart showing a state where a control portion transmits signals in a time-series manner in the projector mounted with the semiconductor laser device according to the seventh embodiment of the present invention.

### DESCRIPTION OF THE PREFERRED EMBODIMENTS

Embodiments of the present invention will be hereinafter described with reference to the drawings.

### First Embodiment

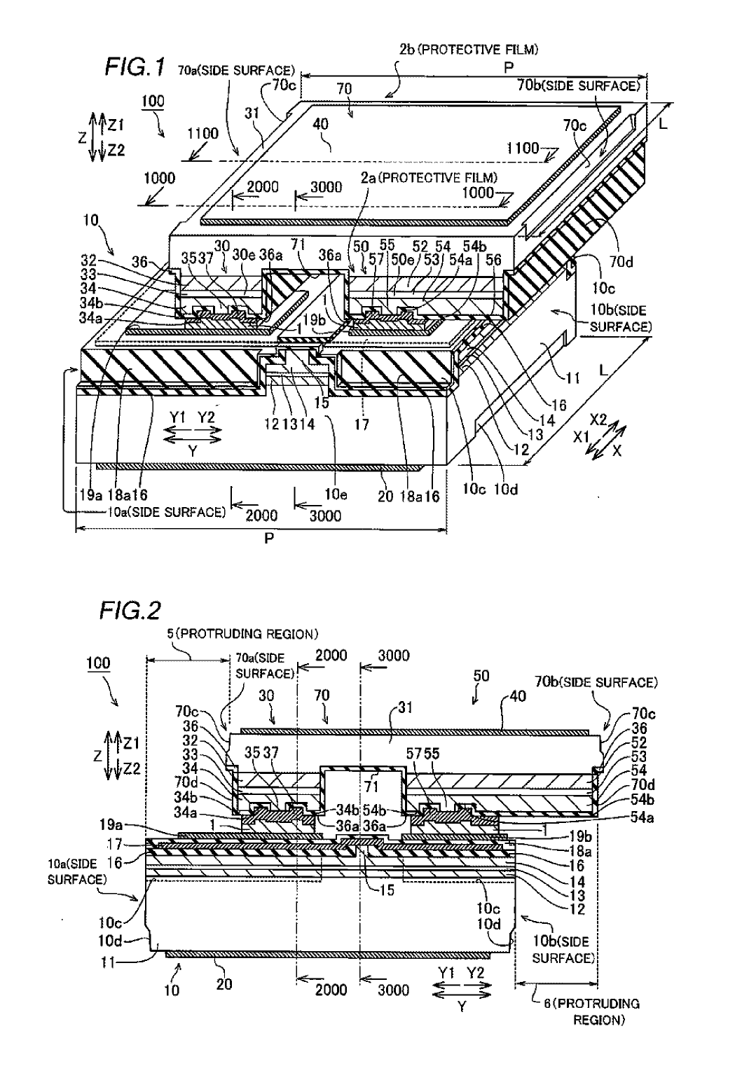

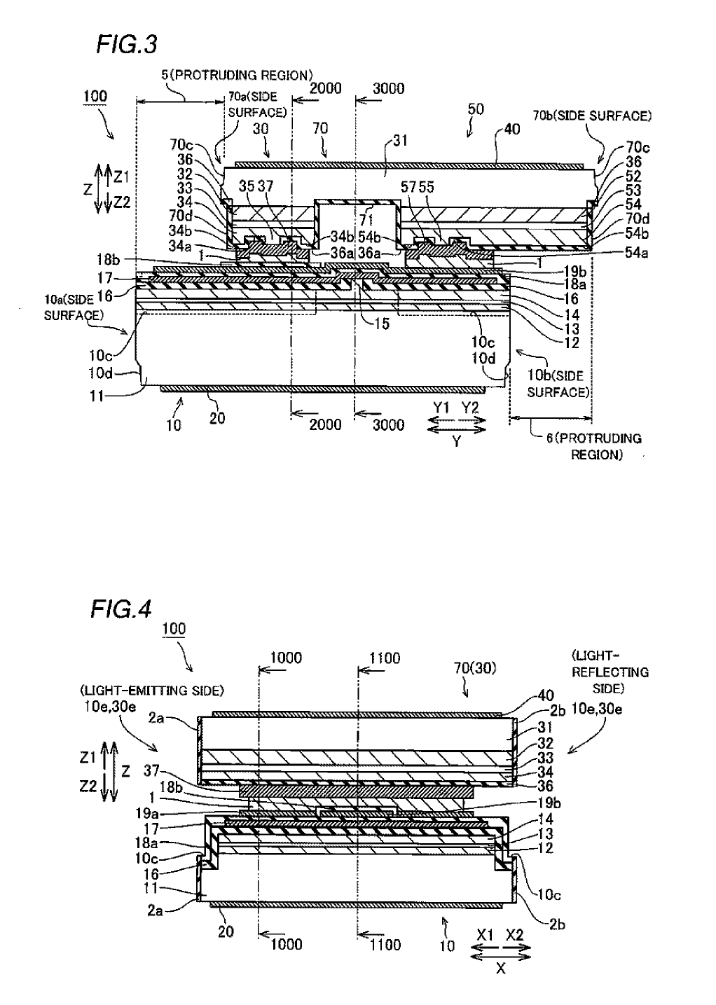

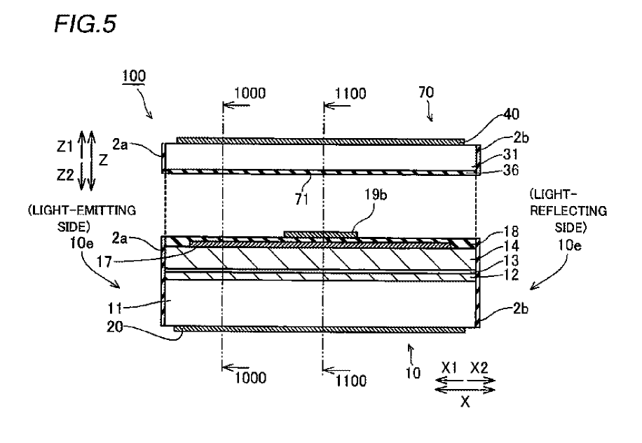

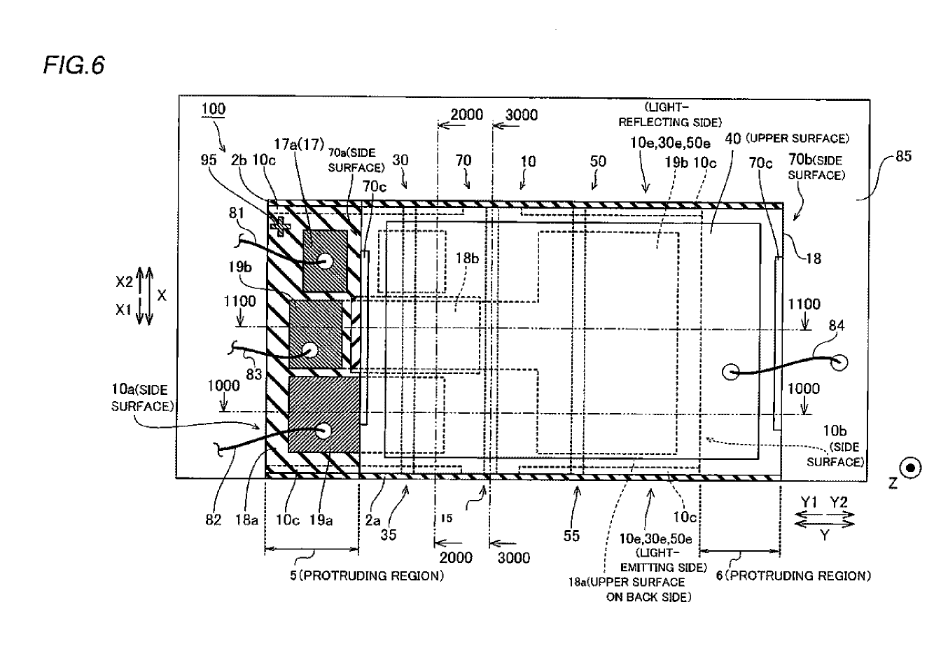

A structure of a semiconductor laser device 100 according to a first embodiment will be now described with reference to FIGS. 1 to 6. The semiconductor laser device 100 is an example of the “integrated semiconductor laser device” in the present invention. FIG. 2 is a sectional view taken along the line 1000-1000 in FIG. 1, and FIG. 3 is a sectional view taken along the line 1100-1100 in FIG. 1. FIG. 4 is a sectional view taken along the line 2000-2000 in FIG. 1, and FIG. 5 is a sectional view taken along the line 3000-3000 in FIG. 1. FIG. 6 is a plan view of the semiconductor laser device shown in FIG. 1.

In the semiconductor laser device 100 according to the first embodiment of the present invention, a two-wavelength semiconductor laser device 70 monolithically formed with a red semiconductor laser device 30 having a lasing wavelength of about 650 nm and an infrared semiconductor laser device 50 having a lasing wavelength of about 780 nm is formed on a surface of a blue-violet semiconductor laser device 10 having a lasing wavelength of about 405 mm, as shown in FIGS. 1 to 5. The blue-violet and two-wavelength semiconductor laser devices 10 and 70 are examples of the “first semiconductor laser device” and the “second semiconductor laser device” in the present invention, respectively.

According to the first embodiment, the blue-violet and two-wavelength semiconductor laser devices 10 and 70 in the semiconductor laser device 100 are bonded to each other in a state where side surfaces of the device 10 extending in a cavity direction (direction X) deviate from side surfaces of the device 70 in a direction Y. The direction X and the direction Y correspond to the “first direction” and the “second direction” in the present invention, respectively. In other words, a side surface 10a on a Y1 side of the blue-violet semiconductor laser device 10 is arranged to deviate in the direction Y1 from a position formed with a side surface 70a on the Y1 side of the two-wavelength semiconductor laser device 70, thereby providing a protruding region 5 exposed from the two-wavelength semiconductor laser device 70 on the blue-violet semiconductor laser device 10, as shown in FIG. 2.

Similarly to the above, a side surface 70b on a Y2 side of the two-wavelength semiconductor laser device 70 is arranged to deviate in a direction Y2 from a position formed with a side surface 10b on the Y2 side of the blue-violet semiconductor laser device 10, thereby providing a protruding region 6 exposed from the blue-violet semiconductor laser device 10 on the two-wavelength semiconductor laser device 70. The protruding regions 5 and 6 are examples of the “first protruding region” and the “second protruding region” in the present invention, respectively. The side surfaces 10a and 10b are examples of the “first side surface” and the “second side surface” in the present invention, respectively, and the side surfaces 70a and 70b are examples of the “third side surface” and the “fourth side surface” in the present invention, respectively.

The blue-violet and two-wavelength semiconductor laser devices 10 and 70 are designed to have substantially equal widths P (=about 200 μm) in the direction Y, and designed to have substantially equal cavity lengths L (=about 800 μm). In other words, a width of the protruding region 5 in the direction Y and a width of the protruding region 6 in the direction Y are substantially equal. However, an error by accuracy of a cleavage/division step is caused in the manufacturing process. Therefore, while the widths P of the blue-violet and two-wavelength semiconductor laser devices 10 and 70 may be different from each other by about 10 μm or the cavity lengths L of the blue-violet and two-wavelength semiconductor laser devices 10 and 70 may be different from each other by about 10 μm, the “substantially equal” as to the cavity lengths L and the widths P includes a case of including such an error.

In the blue-violet semiconductor laser device 10, an n-type cladding layer 12 made of n-type AlGaN, an active layer 13 having a multiple quantum well (MQW) structure and a p-type cladding layer 14 made of p-type AlGaN are formed on a surface of an n-type GaN substrate 11 having a thickness of about 100 μm, as shown in FIG. 2. As shown in FIGS. 1 and 2, the p-type cladding layer 14 has a projecting portion formed on a position approaching the Y2 side from a central portion and projecting in a direction Z1 and planar portions extending to both sides of the projecting portion. The projecting portion of the p-type cladding layer 14 forms a ridge 15 for constituting an optical waveguide on a portion of the active layer 13. The ridge 15 is formed to extend in the direction X (see FIG. 1).

According to the first embodiment, in the blue-violet semiconductor laser device 10, a pair of step portions 10c are formed on both side surfaces of the ridge 15 (in the direction Y) on both ends of the device in the direction X, as shown in FIGS. 1 and 4. These step portions 10c are portions where cleavage guide grooves 91 remain on the blue-violet semiconductor laser device 10 after dividing a wafer-state semiconductor laser device 100 along the direction Y in the form of a bar in a manufacturing process described later.

As shown in FIGS. 1 and 2, an insulating layer 16 made of SiO₂ is formed on the both side surfaces of the ridge 15 of the p-type cladding layer 14 and the upper surfaces of the planar portions. This insulating layer 16 is stacked also on the step portions 10c. A p-side electrode 17 is formed to be in contact with an upper surface of the ridge 15 and cover an upper surface of the insulating layer 16 located around the ridge 15. The p-side electrode 17 is formed to cover the upper surface of the insulating layer 16 except the vicinity of four edges of the upper surface of the blue-violet semiconductor laser device 10. An insulating layer 18a made of SiO₂ is formed on an upper surface of the p-side electrode 17 and an upper surface of the four edges of the insulating layer 16. The insulating layer 18a is formed on bottom surfaces and side surfaces of the step portions 10c (portions stacked with the insulating layer 16). The p-side electrode 17 is an example of the “first electrode” in the present invention.

According to the first embodiment, as shown in FIG. 6, a rectangular wire bonding portion 17a where the lower p-side electrode 17 is partly exposed by partly removing the insulating layer 18a is formed on the portion of the insulating layer 18a, located on the protruding region 5 protruding sideward to the Y1 side from the position formed with the side surface 70a on the Y1 side of the two-wavelength semiconductor laser device 70 on the upper surface on the Y1 side of the blue-violet semiconductor laser device 10. As shown in FIGS. 2 and 6, a pad electrode 19a extending from a region bonded with the red semiconductor laser device 30 to the protruding region 5 on the Y1 side is formed on a region on the X1 and Y1 sides of the insulating layer 18a on the protruding region 5. As shown in FIGS. 3 and 6, on the surface of the insulating layer 18a, a pad electrode 19b is so formed to oblongly cover the Y2 side of this surface, bonded with the infrared semiconductor laser device 50, along the direction X while extending from a substantially central portion of the direction X to the protruding region 5 on the Y1 side across a portion above the ridge 15. At this time, an insulating layer 18b made of SiO₂ is formed between the pad electrode 19b and the red semiconductor laser device 30 on the region bonded with the red semiconductor laser device 30, thereby insulating the pad electrode 19b and the red semiconductor laser device 30, as shown in FIGS. 3 and 4. The upper surface of the blue-violet semiconductor laser device 10 is an example of the “first surface” in the present invention, and the pad electrodes 19a and 19b are each an example of the “second electrode” in the present invention.

According to the first embodiment, the wire bonding portion 17a and the pad electrodes 19a and 19b are formed on the protruding region 5 of the blue-violet semiconductor laser device 10 to align along the cavity direction (direction X) in a state not in contact with each other on the protruding region 5 of the blue-violet semiconductor laser device 10.

As shown in FIGS. 1 to 4, an n-side electrode 20 is formed on a lower surface of the n-type GaN substrate 11 except regions formed with step portions 10d and the vicinity of these regions. These step portions 10d formed on both ends (side surfaces 10a and 10b) in the direction Y of the lower surface of the blue-violet semiconductor laser device 10 are portions where division grooves 73 remain on the blue-violet semiconductor laser device 10 after dividing a bar-shaped semiconductor laser device 100 along the direction Y into chips in the manufacturing process described later. The bar-shaped semiconductor laser device 100 is an example of the “third oblong substrate” in the present invention, and the division groove 73 is an example of the “first division groove” in the present invention.

In the red semiconductor laser device 30 constituting the two-wavelength semiconductor laser device 70, an n-type cladding layer 32 made of n-type AlGaInP, an active layer 33 having an MQW structure and a p-type cladding layer 34 made of p-type AlGalnP are formed on a lower surface of an n-type GaAs substrate 31 having a thickness of about 100 μm, as shown in FIG. 2. In the infrared semiconductor laser device 50, an n-type cladding layer 52 made of n-type AlGaAs, an active layer 53 having an MQW structure and a p-type cladding layer 54 made of p-type AlGaAs are formed on the lower surface of the n-type GaAs substrate 31. As shown in FIGS. 1, 2 and 4, a groove 71 is formed on a region (central portion in the direction Y) held between the red and infrared semiconductor laser devices 30 and 50.

The p-type cladding layers 34 and 54 have projecting portions formed on substantially central portions in the direction Y and projecting in a direction Z2, recess portions 34a and 54a formed on both sides of the projecting portions and extending in the direction X, planar portions 34b and 54b extending to both sides of the recess portions 34a and 54a, respectively. The projecting portions of the p-type cladding layers 34 and 54 form ridges 35 and 55 for constituting optical waveguides on portions of the active layers 13 and 53. The ridges 35 and 55 are formed to extend in the direction X, as shown in FIGS. 1 and 5.

As shown in FIGS. 1 and 2, an insulating layer 36 made of SiO₂ is formed on lower surfaces of the p-type cladding layers 34 and 54 except lower surfaces of the ridges 35 and 55, side surfaces of the red and infrared semiconductor laser devices 30 and 50, and a lower surface of the groove 71 of the n-type GaAs substrate 31. The insulating layer 36 has a substantially uniform thickness and is formed also on inner side surfaces (bottom and side surfaces of the recess portion) of the recess portion 34a (54a) of the p-type cladding layer 34 (54). Thus, the insulating layer 36 has recess portions formed on the both sides of the ridges 35 and 55 and planar portions 36a extending to the both sides of the recess portions so as to correspond to relief of the p-type cladding layers 34 and 54.

The planar portions 36a are formed to be located below the lower surfaces (surfaces on the Z2 side) of the ridges 35 and 55 formed with no insulating layer 36, as shown in FIG. 2. Thus, excessive pressure can be inhibited from being applied to the ridges 35 and 55 when the lower surface of the two-wavelength semiconductor laser device 70 is bonded onto the blue-violet semiconductor laser device 10. The lower surface of the two-wavelength semiconductor laser device 70 is an example of the “second surface” in the present invention.

A p-side electrode 37 is formed to be in contact with a lower surface of the ridge 35 and cover a lower surface of the insulating layer 36 located around the ridge 35. Further, a p-side electrode 57 is formed to be in contact with a lower surface of the ridge 55 and cover a lower surface of the insulating layer 36 located around the ridge 55. These p-side electrodes 37 and 57 have substantially uniform thicknesses and are formed with surface relief corresponding to the relief of the insulating layer 36.

An n-side electrode 40 is formed on an upper surface (surface on a Z1 side) of the n-type GaAs substrate 31 except regions formed with step portions 70c, described later, and regions in the vicinity thereof. This n-side electrode 40 is employed in common for the red and infrared semiconductor laser devices 30 and 50. The step portions 70c and 70d extending' in the direction X are formed on both ends (side surfaces 70a and 70b) of the two-wavelength semiconductor laser device 70 in the direction Y. These step portions 70c and 70d are portions where division grooves 74 remain on the two-wavelength semiconductor laser device 70 after dividing the bar-shaped semiconductor laser device 100 along the direction X into chips in the manufacturing process described later. The division groove 74 is an example of the “second division groove” in the present invention.

As shown in FIGS. 2 and 3, the p-side electrodes 37 and 57 are bonded onto the pad electrodes 19a and 19b on the blue-violet semiconductor laser device 10 through fusion layers 1 made of Au—Sn solder, respectively. The step portions 10c of the blue-violet semiconductor laser device 10 are formed to extend up to portions located below (in the direction Z2) a position formed with the red or infrared semiconductor laser device 30 or 50. The two-wavelength semiconductor laser device 70 is so arranged that the portion of the groove 71 completely covers above the ridge 15 (waveguide) of the blue-violet semiconductor laser device 10. Thus, a light-emitting point of the blue-violet semiconductor laser device 10 and light-emitting points of the two-wavelength semiconductor laser device 70 can be brought close to each other in the direction Z.

According to the first embodiment, pairs of cavity facets 10e, 30e and 50e which are planes (corresponding to a Y-Z plane in FIG. 6) perpendicular to the extensional direction of the ridges 15, 35 and 55 are formed on both ends on the X sides of the blue-violet, red and infrared semiconductor laser devices 10, 30 and 50, respectively, as shown in FIG. 6. All cavity facets on the X1 side are located in the same plane on the X1 side and all cavity facets on the X2 side are located in the same plane on the X2 side. Protective films 2a and 2b having a function of reflectance control and made of AlN or Al₂O₃ are formed on the cavity facets 10e, 30e and 50e by facet coating process in the manufacturing process.

The protective film 2a formed on the cavity facet 10e (30e, 50e) on a light-emitting side is formed by an AlN film having a thickness of about 10 nm and an Al₂O₃ film having a thickness of about 150 nm from the cavity facet 10e (30e, 50e) toward outside. The protective film 2b formed on the cavity facet on a light-emitting side is formed by an AlN film having a thickness of about 10 nm, an Al₂O₃ film having a thickness of about 30 nm, an AlN film having a thickness of about 10 nm, an Al₂O₃ film having a thickness of about 60 nm, an SiO₂ film having a thickness of about 140 nm and a multilayer reflector having a thickness of about 708 nm in total, formed by alternately stacking six SiO₂ films each having a thickness of about 68 nm as a low refractive index film and six ZrO2 films each having a thickness of about 50 nm as a high refractive index film from the cavity facet toward outside. As shown in FIG. 6, the blue-violet semiconductor laser device 10 is connected to a lead terminal through a metal wire 81 bonding to a wire bonding portion 17b of the protruding region 5, and the n-side electrode 20 (see FIG. 1) is electrically fixed to a substrate 85 through a fusion layer. The red semiconductor laser device 30 is connected to a lead terminal through a metal wire 82 bonding to the pad electrode 19a exposed on the protruding region 5. The infrared semiconductor laser device 50 is connected to a lead terminal through a metal wire 83 bonding to the pad electrode 19b exposed on the protruding region 5. The two-wavelength semiconductor laser device 70 is electrically connected to the substrate 85 through a metal wire 84 bonding to an upper surface of the n-side electrode 40 opposite to a bonding surface. In FIG. 6, the n-side electrode 40 (shown by a solid line) in the uppermost part is not hatched in order to show the shapes of the pad electrodes 19a and 19b hiding behind the two-wavelength semiconductor laser device 70 for convenience sake. The metal wire 81 is an example of the “first metal wire” in the present invention, and the metal wires 82 and 83 are each an example of the “second metal wire” in the present invention.

The manufacturing process for the semiconductor laser device 100 according to the first embodiment will be now described with reference to FIGS. 1, 2 and 6 to 15.

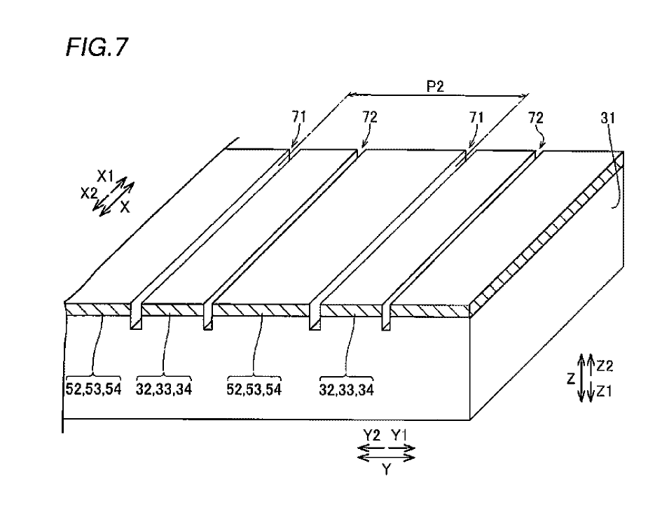

The n-type cladding layer 52, the active layer 53 and the p-type cladding layer 54 constituting the infrared semiconductor laser device 50 are successively formed on the prescribed region of the upper surface of the wafer-state n-type GaAs substrate 31 by low-pressure MOCVD as shown in FIG. 7. The n-type cladding layer 52, the active layer 53 and the p-type cladding layer 54 are partly etched to partly expose the n-type GaAs substrate 31, and the n-type cladding layer 32, the active layer 33 and the p-type cladding layer 34 constituting the red semiconductor laser device 30 are successively formed on the partly exposed positions while regions employed as the grooves 71 remain. In FIG. 7, the semiconductor layer formed through the aforementioned steps is shown by a single layer (hatched region) for convenience sake.

Division grooves 72 having a depth of about 5 μm in the direction Z1 from a surface of the semiconductor layer and extending in the direction X are formed by photolithography and etching. At this time, the division grooves 72 are so formed that an interval in the direction Y is equal to a pitch P2 at a temperature T1 in alignment at a subsequent wafer bonding step. The division grooves 72 are formed to reach up to the n-type GaAs substrate 31 located under the semiconductor layer. The division grooves 72 are formed to have substantially the same depth as the grooves 71. The division groove 72 is an example of the “third division groove” in the present invention.

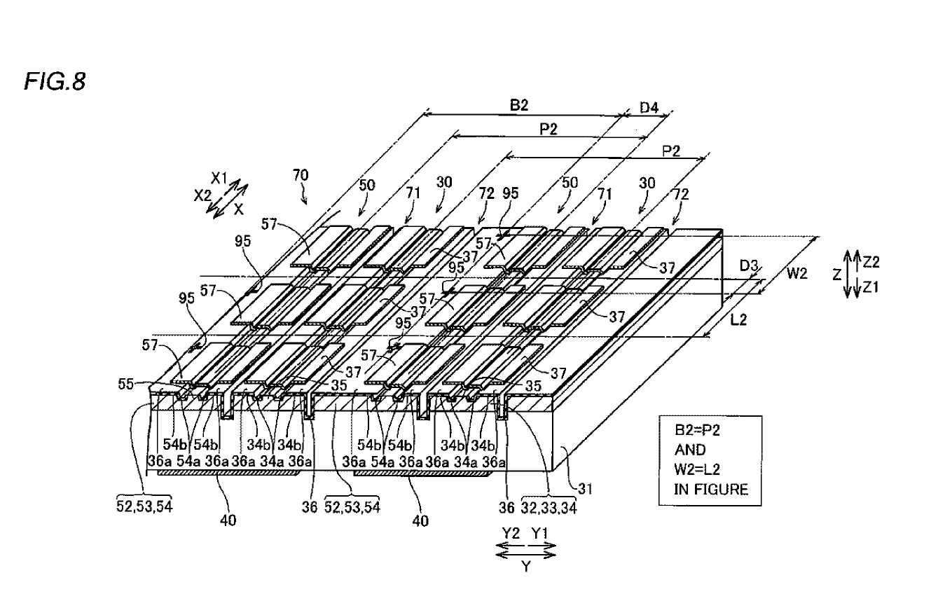

As shown in FIG. 8, prescribed regions of the p-type cladding layers 34 and 54 are removed by photolithography and etching, thereby forming the ridges 35 and 55 extending along the direction X. At this time, the ridges 35 and 55 are so formed that respective intervals thereof in the direction Y are equal to the pitches P2 at the temperature T1 in alignment at the subsequent wafer bonding step. The intervals of the ridges 35 and 55 in the direction Y (distance P2 shown in FIG. 8) each correspond to the “second period” in the present invention. The recess portions 34a and 54a on both sides of the ridges 35 and 55 and the planar portions 34b and 54b extending to the both sides of the recess portions 34a and 54a are formed by removing the prescribed regions of the p-type cladding layers 34 and 54 simultaneously with formation of the ridges.

The insulating layer 36 is formed on the upper surfaces of the p-type cladding layers 34 and 54 by plasma CVD. At this time, the insulating layer 36 is stacked also on inside of the grooves 71 and the division grooves 72 exposing the n-type GaAs substrate 31, and the planar portions 36a are also formed. The insulating layer 36 formed on the upper surfaces of the ridges 35 and 55 is removed by photolithography and etching. Thus, the planar portions 36a are formed to be located above the upper surfaces of the ridges 35 and 55 (on a Z2 side).

Thereafter, metal layers 37 and 57 are stacked on the upper surfaces of the ridges 35 and 55 and the upper surface of prescribed regions of the insulating layer 36 in the in-plane shapes corresponding to the individual two-wavelength semiconductor laser devices 70 after division into chips by vacuum evaporation and lift-off method. At this time, alignment marks 95 for alignment in wafer bonding are formed an the upper surface of the insulating layer 36. These alignment marks 95 are provided to have a pitch W2 and a pitch B2 in the direction X and the direction 1, respectively. FIG. 8 shows the alignment marks 95 formed in the vicinity of the central portion of the wafer of the two-wavelength semiconductor laser device 70. The alignment mark 95 is example of the “second alignment mark” in the present invention, and the direction X or Y in FIG. 8 corresponds to the “third direction” in the present invention.

The lower surface of the n-type GaAs substrate 31 is so etched that the n-type GaAs substrate 31 has a thickness of about 100 μm, and a metal layer 40 is thereafter patterned on prescribed regions of the lower surface of the n-type GaAs substrate 31 by vacuum evaporation and photolithography. In this state, the wafer is subjected to thermal treatment at about 400° C. Thus, the ridges 35 and 55 and the metal layers 37 and 57 are alloyed respectively. And the lower surface of the n-type GaAs substrate 31 and the metal layer 40 are alloyed to form the n-side electrodes 40, as shown in FIG. 8. Thus, the semiconductor layer and the p-side electrodes 37 (57), and the n-type GaAs substrate 31 and the n-side electrodes 40 are brought into ohmic contact with each other. The wafer-state two-wavelength semiconductor laser device 70 is prepared in the aforementioned manner. The wafer-state two-wavelength semiconductor laser device 70 is an example of the “second semiconductor laser device substrate” in the present invention.

In the manufacturing process according to the first embodiment, the alignment marks 95 on the wafer of the two-wavelength semiconductor laser device 70 are so formed that the pitch W2 in the direction X is equal to a cavity length L2 (W2=L2) while the pitch B2 in the direction Y is equal to each of ridge intervals (pitches P2) of the red and infrared semiconductor laser devices 30 and 50 (B2=P2), as shown in FIG. 8. The pitches W2 and B2 each correspond to the “fourth period” in the present invention. A distance D3 from each alignment mark 95 to the closest cleavage plane of each device in the wafer-state two-wavelength semiconductor laser device 70 is equal to each other. The pitch W2, the cavity length L2, the pitch B2 and the pitch P2 shown in FIG. 8 show lengths at the temperature T1 (around room temperature (about 30° C.), for example) in alignment at the wafer bonding step.

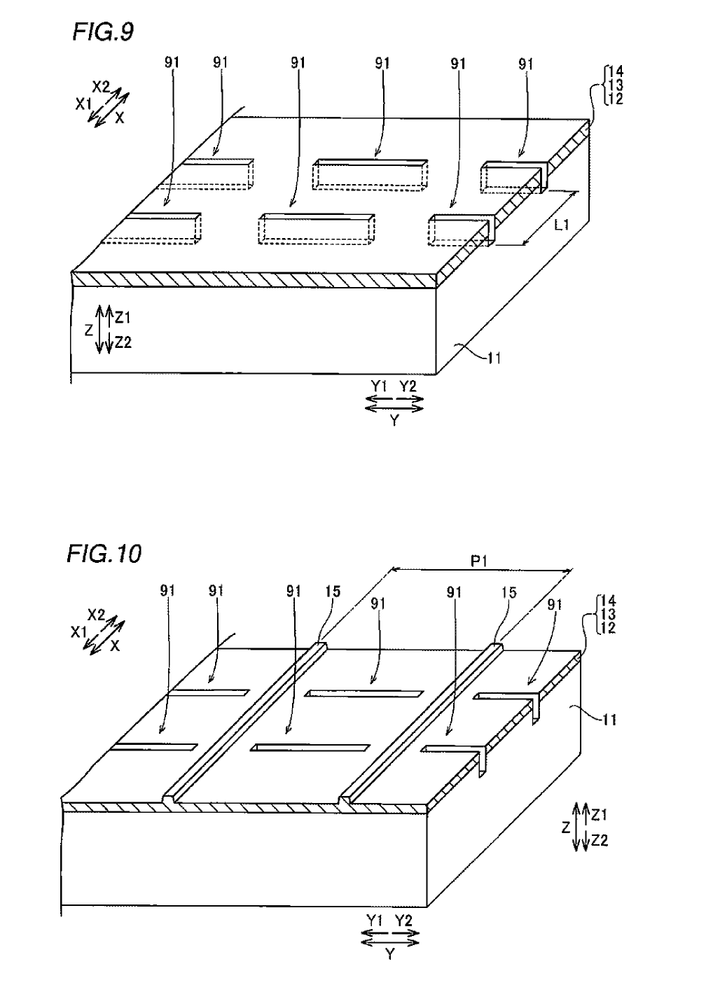

As shown in FIG. 9, the n-type cladding layer 12, the active layer 13 and the p-type cladding layer 14 are successively stacked on the upper surface of the n-type GaN substrate 11 whose main surface is a (0001) plane by low-pressure MOCVD.

Cleavage guide grooves 91 having a depth of about 5 μm in the direction Z2 from the p-type cladding layer 14 side and extending along the direction Y are formed by photolithography and etching. At this time, the cleavage guide grooves 91 are formed in the form of broken lines except regions (see FIG. 10) formed with the ridges 15 of the blue-violet semiconductor laser device 10 and regions in the vicinity thereof. The cleavage guide grooves 91 are so formed that intervals in the direction X are equal to a cavity length L1 at the temperature T1 in alignment at the subsequent wafer bonding step. The cleavage guide grooves 91 are formed to reach up to the n-type GaN substrate 11 located under the semiconductor layer. Thus, the n-type GaN substrate 11 employed as a nitride-based semiconductor which is generally difficult to be cleaved and the semiconductor layer can be more reliably cleaved. The interval (distance L1 shown in FIG. 9) of the cleavage guide grooves 91 in the direction X corresponds to the “fifth period” in the present invention.

As shown in FIG. 10, prescribed regions of the p-type cladding layer 14 are removed by photolithography and etching, thereby forming the ridges 15 extending along the direction X. At this time, the cleavage guide grooves 91 having a depth (about 5 μm) larger than a projecting height of the ridges 15 are formed on the semiconductor layer, and hence the cleavage guide grooves 91 remain on the semiconductor layer also after forming the ridges 15. The ridges 15 are so formed that the interval in the direction Y is equal to a pitch P1 at the temperature T1 in alignment at the subsequent wafer bonding step. The interval (distance P1 shown in FIG. 10) of the ridges 15 in the direction Y corresponds to the “first period” in the present invention.

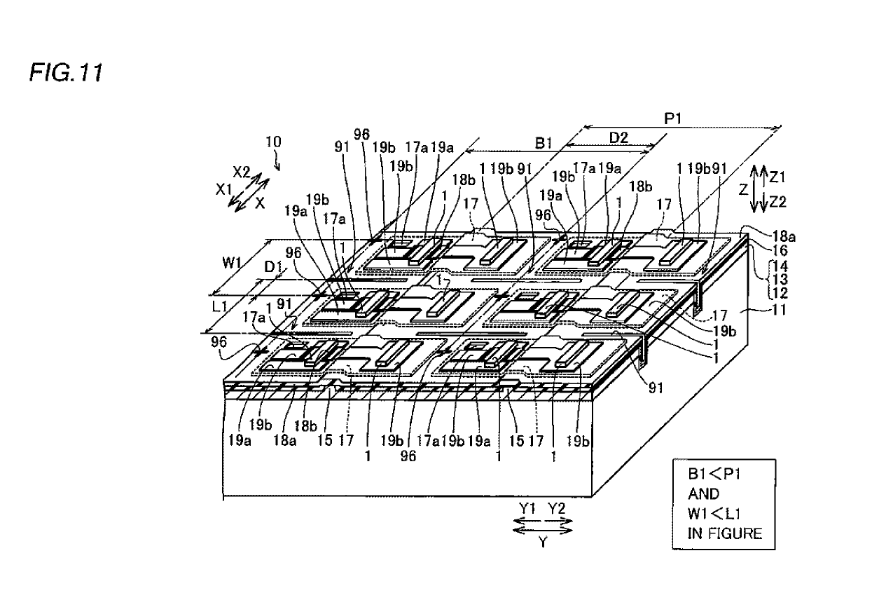

As shown in FIG. 11, the insulating layer 16 is formed to cover the side surfaces of the ridges 15 of the p-type cladding layer 14 and the upper surfaces of the planar portions by plasma. CVD. At this time, the insulating layer 16 is stacked also on inner side surfaces of the cleavage guide grooves 91. The insulating layer 16 on the upper surfaces of the ridges 15 is removed, and a metal layer is thereafter stacked on the upper surfaces of the ridges 15 and the upper surface of the insulating layer 16 in the in-plane shapes corresponding to the individual blue-violet semiconductor laser devices 10 after division into chips by vacuum evaporation. Then, the metal layer is alloyed by thermal treatment at about 400° C., thereby forming the p-side electrodes 17.

The insulating layer 18a covering the upper surfaces of the p-side electrodes 17 and the upper surface of the insulating layer 16 is formed by plasma CVD. At this time, the insulating layer 18a is stacked also on inside the cleavage guide grooves 91 and the upper surface of the insulating layer 16. Prescribed regions of the insulating layer 18a are removed by photolithography and etching, so that the wire bonding portions 17a are formed while the p-side electrodes 17 are partly exposed in the direction Z1.

Thereafter, the patterned pad electrodes 19a and 19b are formed on the upper surfaces of prescribed regions of the insulating layer 18a in the in-plane shapes corresponding to the individual blue-violet semiconductor laser devices 10 after division into chips by vacuum evaporation and lift-off method. At this time, alignment marks 96 for alignment in wafer bonding are formed on the upper surface of the insulating layer 18a. These alignment marks 96 are provided to have a pitch W1 and a pitch B1 in the direction X and the direction Y, respectively. The pad electrodes 19a and 19b are also patterned at the same pitches (pitches W1 and B1) as the alignment marks 96. The pitches W1 and B1 each correspond to the “third period” in the present invention. Thus, the pad electrodes 19a and 19b are simultaneously formed at the same pitches as the alignment marks 96, and hence a step of forming the alignment marks 96 is simplified. Mask patterns for forming the pad electrodes 19a and 19b and the alignment marks 96 are repeatedly formed at the same pitch, and hence masks can be easily prepared. FIG. 11 shows the alignment marks 96 formed in the vicinity of the central portion of the wafer of the blue-violet semiconductor laser device 10. The alignment marks 96 on the wafer of the blue-violet semiconductor laser device 10 at the temperature T1 are so formed that the pitch W1 in the direction X is equal to the pitch W2 of the alignment marks 95 (W1=W2) while the pitch B1 in the direction Y equal to the pitch B2 of the alignment marks 95 (B1=B2). The alignment mark 96 is an example of the “first alignment mark” in the present invention, and the direction X or Y in FIG. 11 corresponds to the “third direction” in the present invention.

The insulating layer 18b is formed on the pad electrodes 19b while the upper surface on the Y1 side of each pad electrode 19b partly remains exposed. Thereafter, the fusion layers 1 are formed on positions bonded with the ridges of the two-wavelength semiconductor laser device 70 on the exposed insulating layers 18b, pad electrodes 19a and 19b. Thus, the wafer-state blue-violet semiconductor laser device 10 except the n-side electrodes (see FIG. 1) are prepared. The wafer-state blue-violet semiconductor laser device 10 is an example of the “first semiconductor laser device substrate” in the present invention.

A thermal expansion coefficient of GaN is isotropic with respect to an in-plane of a c-plane substrate, and a thermal expansion coefficient α1 (=5.0×10⁻⁶/K) of GaN in an a-axis direction is smaller than a thermal expansion coefficient α2 (=6.03×10⁻⁶/K) of GaAs, and hence the cavity length and the ridge interval of the wafer of the blue-violet semiconductor laser device 10 are different from those of the wafer of the two-wavelength semiconductor laser device 70 at a bonding temperature at the wafer bonding step (about 300° C., for example) if the cavity length L1 and the ridge interval P1 of the blue-violet laser device are prepared to satisfy P1=P2 and L1=L2 at the temperature T1. Consequently, the intervals between the waveguides of the blue-violet semiconductor laser devices and the waveguides of the two-wavelength semiconductor laser devices are not disadvantageously constant among the individual divided chips.

In order to solve this disadvantage, the ridge interval of the blue-violet semiconductor laser device 10 and the ridge intervals of the two-wavelength semiconductor laser device 70 must coincide with each other at a bonding temperature T2. In other words, in each laser device at the bonding temperature T2, the cavity length must satisfy the relation of L1×(1+α1×ΔT)=L2×(1+α2×ΔT), and the ridge interval must satisfy the relation of P1×(1+α1×ΔT)=P2×(1+α2×ΔT), where ΔT, T1 and T2 satisfy ΔT=T2−T1.

Therefore, the cavity length L1 and the ridge interval P1 of the blue-violet semiconductor laser device at the temperature T1 must be set to satisfy L1=L2×{(1+α2×ΔT)/(1+α1×ΔT)}>L2, and P1=P2×{(1+α2×ΔT)/(1+α1×ΔT)}>P2. In other words, the cavity length L1 and the ridge interval P1 of the wafer of the blue-violet semiconductor laser device 10 must be set to be larger than the cavity length L2 and the ridge interval P2 of the wafer of the two-wavelength semiconductor laser device 70.

In the wafer of the blue-violet semiconductor laser device 10, the cavity length L1 is set to be larger than the pitch W1 of the alignment marks 96 (L1>W1) and the ridge interval (pitch P1) is set to be larger than the pitch B1 of the alignment marks 96 (P1>B1), as shown in FIG. 11.

Thus, a distance D1 from each alignment mark 96 of the wafer of the blue-violet semiconductor laser device 10 to the closest cleavage plane and a distance D2 from each alignment mark 96 to the closest ridge 15 are not constant among the individual devices. For example the distance D1 on the central portion of the wafer of the blue-violet semiconductor laser device 10 substantially coincides with the distance D3 in FIG. 8.

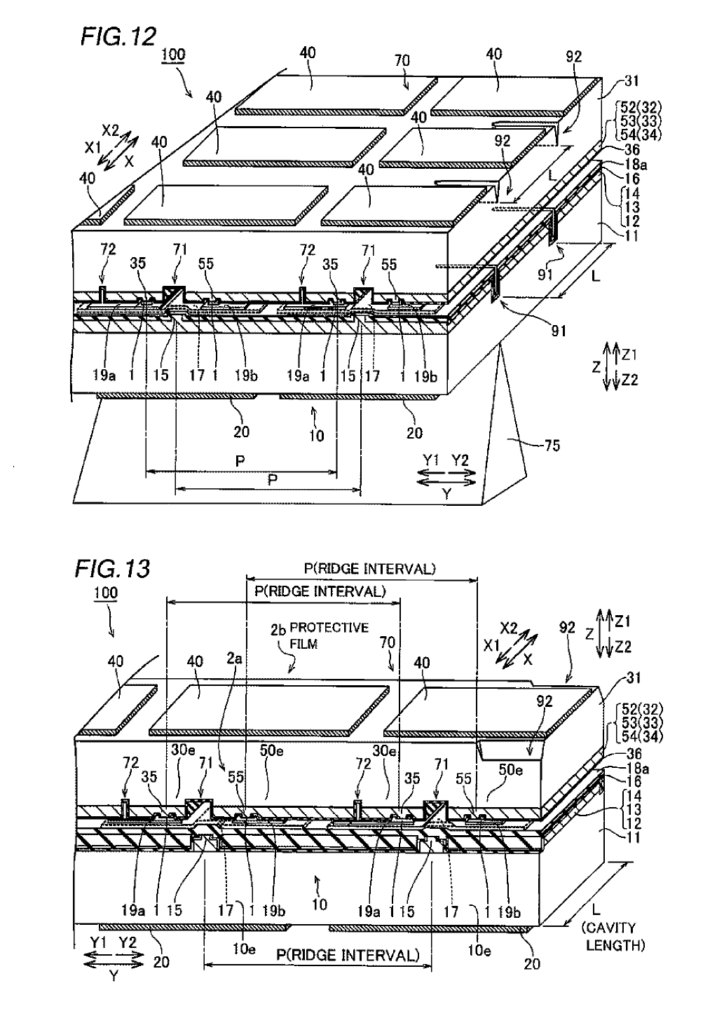

As shown in FIG. 12, the wafer-state blue-violet semiconductor laser device 10 and the wafer-state two-wavelength semiconductor laser device 70 are so aligned that the alignment marks 95 and 96 overlap with each other while the pad electrodes 19a and 19b are opposed to the p-side electrodes 37 and 57, respectively, between the wafer-state blue-violet semiconductor laser device 10 and the wafer-state two-wavelength semiconductor laser device 70. At this time, alignment is so performed that positions employed as the cleavage planes of the blue-violet semiconductor laser and positions employed as the cleavage planes of the two-wavelength semiconductor laser substantially coincide with each other on the substantially central portion of the wafer while the intervals between the waveguides of the blue-violet semiconductor laser device 10 and the waveguides of the two-wavelength semiconductor laser device 70 are set values.

A temperature is increased so as not to cause deviation on the substantially central portion of the wafers shown in FIGS. 8 and 11, and bonding is performed with the fusion layers 1 at the bonding temperature T2 of at least about 200° C. and not more than about 350° C. Consequently, on the bonded wafers of FIG. 12, the intervals between the waveguides of the blue-violet semiconductor laser device 10 and the waveguides of the two-wavelength semiconductor laser device 70 are constant in the wafers and positions employed as the cleavage planes of the blue-violet semiconductor laser device 10 and positions employed as the cleavage planes of the two-wavelength semiconductor laser device 70 substantially coincide. The ridge interval P and the cavity length L are illustrated by ignoring difference between the pitches P1 and P2 and difference between the cavity lengths L1 and L2. On the other hand, the deviation between the alignment marks 95 and 96 formed on both of the wafers are small on the central portions of the wafers, while the deviation between the alignment marks 95 and 96 is increased as the alignment marks 95 and 96 are separated from the central portions of the wafers to the peripheral portions due to influence of thermal expansion of the substrates.

While the positions of the pad electrodes (17, 19a and 19b) are deviated in some degree in the directions X and Y among the individual blue-violet semiconductor laser devices 10, this poses little problem for device characteristics.

As shown in FIG. 12, the lower surface of the n-type GaN substrate 11 is so polished that the n-type GaN substrate 11 has a thickness of about 100 μm, the n-side electrodes 20 are thereafter patterned on prescribed regions of the lower surface of the n-type GaN substrate 11 by vacuum evaporation and photolithography. Thermal treatment is not performed when forming the n-side electrodes 20.

In the manufacturing process according to the first embodiment, the cleavage guide grooves 92 are formed on both ends of each n-side electrode 40 in the direction Y with a diamond point. At this time, the cleavage guide grooves 92 are formed so as to overlap with the cleavage guide grooves 91 formed on the blue-violet semiconductor laser device 10 as viewed from a direction Z. The cleavage guide grooves 92 are not formed on regions other than the ends of the wafer-state n-type GaAs substrate 31 in the direction Y. The interval (distance L shown in FIG. 12) of the cleavage guide grooves 92 in the direction X corresponds to the “sixth period” in the present invention.

In this state, an edged tool 75 is pressed from the lower surface side of the blue-violet semiconductor laser device 10, thereby cleaving the wafer along the direction Y where the cleavage guide grooves 91 extend. Thus, the bar-shaped semiconductor laser device 100 is formed as shown in FIG. 13. At this time, a pair of the cavity facets 10e (see FIG. 6) are formed on the bar-shaped blue-violet semiconductor laser device 10. Similarly, pairs of the cavity facets 30e and 50e (see FIG. 6) are formed on the bar-shaped two-wavelength semiconductor laser device 70. The cleavage guide grooves 91 partially remain, thereby forming the step portions 10c. The bar-shaped blue-violet semiconductor laser device 10 and the bar-shaped two-wavelength semiconductor laser device 70 are examples of the “first oblong substrate” and the “second oblong substrate” in the present invention, respectively.

In the manufacturing process according to the first embodiment, the bar-shaped semiconductor laser device 100 is subjected to facet coating process. Thus, the protective film 2a is formed on the cavity facets 10e, 30e and 50e on the X1 side (light-emitting side), and the protective film 2b is formed on cavity facets 10e, 30e and 50e on the X2 side (light-reflecting side), as shown in FIG. 13.

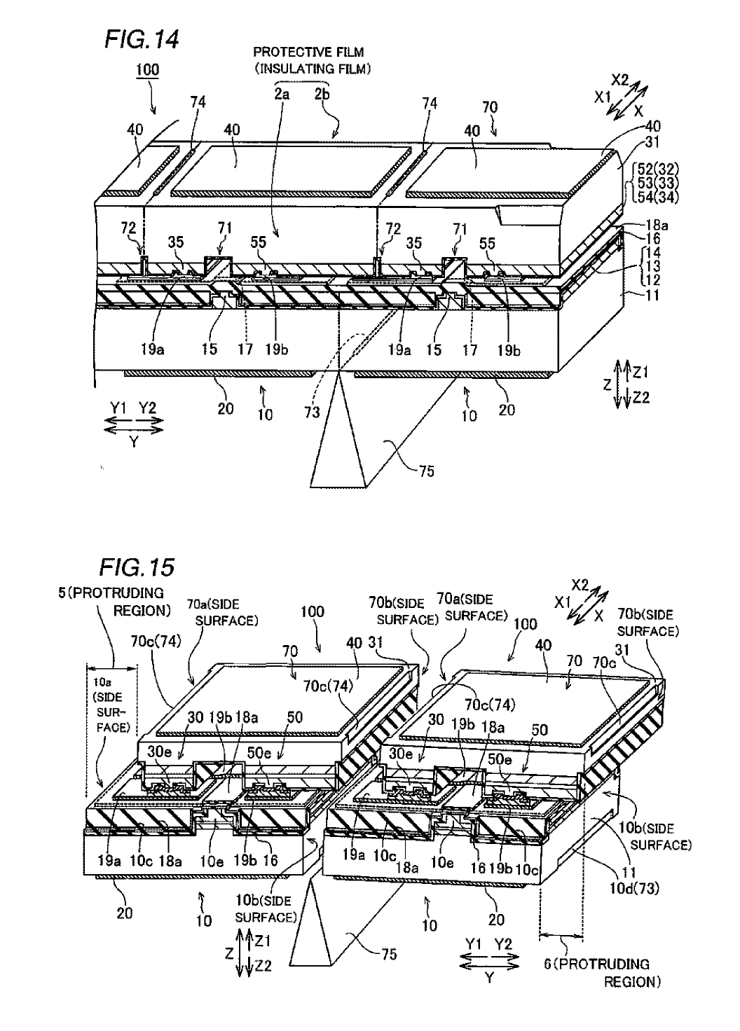

As shown in FIG. 14, the division grooves 73 (shown by broken lines) extending along the direction X are formed on the surface (lower surface) between the n-side electrodes 20 with the diamond point, and the division grooves 74 extending along the direction X are formed on the surfaces of the n-side electrodes 40 on positions opposed to the division grooves 72. At this time, division grooves 73 and 74 are formed on positions deviated from each other in the direction Y.

In this state, the edged tool 75 is pressed from the lower surface side of the blue-violet semiconductor laser device 10, thereby dividing the wafer along the direction X where the division grooves 73 extend. At this time, the bar-shaped blue-violet semiconductor laser device 10 is separated in the direction Y on the division grooves 73, the bar-shaped two-wavelength semiconductor laser device 70 is separated in the direction Y on the division grooves 74. As shown in FIG. 15, chips are formed in a state where the side surfaces 10a of the blue-violet semiconductor laser devices 10 are deviated in the direction Y1 with respect to the side surfaces 70a of the two-wavelength semiconductor laser devices 70 while the side surfaces 70b of the two-wavelength semiconductor laser devices 70 are deviated in the direction Y2 with respect to the side surfaces 10b of the blue-violet semiconductor laser devices 10.

The wire bonding portion 17a (see FIG. 6) of each blue-violet semiconductor laser device 10 is exposed outside by this device division. The division grooves 73 partially remain the both ends of the blue-violet semiconductor laser device 10 in the direction Y, so that the step portions 10d are formed, while the division grooves 74 partially remain on the both ends of the two-wavelength semiconductor laser device 70 in the direction Y, so that the step portions 70c and 70d are formed. The chips of the semiconductor laser device 100 according to the first embodiment are formed in the aforementioned manner.

According to the first embodiment, as hereinabove described, the blue-violet and two-wavelength semiconductor laser devices 10 and 70 are bonded to each other so that the side surface 10a of the blue-violet semiconductor laser device 10 protrudes sideward to the Y1 side from the position formed with the side surface 70a of the two-wavelength semiconductor laser device 70 while the side surface 70b of the two-wavelength semiconductor laser device 70 protrudes sideward to the Y2 side from the position formed with the side surface 10b of the blue-violet semiconductor laser device 10. In other words, the semiconductor laser device 100, in which the respective side surfaces of the blue-violet and two-wavelength semiconductor laser devices 10 and 70 are bonded on the positions deviated from each other in the direction Y, is formed, whereby the chips of the semiconductor laser device 100 can be formed by dividing the wafer without removing unnecessary portions of the wafer dissimilarly to a manufacturing process where unnecessary portions of the wafer of the two-wavelength semiconductor laser device 70 are previously removed from the wafer bonded with the wafer-state blue-violet and two-wavelength semiconductor laser devices 10 and 70 and the two-wavelength semiconductor laser device 70 having a device width smaller in an inner direction of the device than the side surfaces 10a and 10b is formed on the surface of the wafer of the blue-violet semiconductor laser device 10, and the wafer is thereafter divided into chips. Thus, the yield of the semiconductor laser device 100 can be improved.

According to the first embodiment, the metal wire 81 is bonded to the p-side electrode 17 (wire bonding portion 17a) on the portion of the p-side electrode 17, exposed on the surface of the protruding region 5 of the blue-violet semiconductor laser device 10, protruding sideward to the Y1 side from the two-wavelength semiconductor laser device 70. In other words, no step of etching from the two-wavelength semiconductor laser device 70 side after bonding the wafers to expose the p-side electrodes 17 for bonding the metal wire 81 on the surface of the blue-violet semiconductor laser device 10, for example, may be separately performed in the manufacturing process, and hence the manufacturing process of the semiconductor laser device 100 can be simplified because of unnecessity of such a step.

According to the first embodiment, the pad electrodes 19a and 19b are formed to extend to the protruding region from a portion between the two-wavelength semiconductor laser device 70 and the insulating layer 18a, whereby not only the p-side electrode 17 but also the pad electrodes 19a and 19b can be easily connected to the outside from the protruding region 5 of the blue-violet semiconductor laser device 10.

According to the first embodiment, the pad electrode 19a is connected to the metal wire 82, and the pad electrode 19b is connected to the metal wire 82, whereby the metal wires 82 and 83 connected to the outside can be bonded to the respective pad electrode 19a and 19b on the same side as the metal wire 81, and hence the three metal wires can be arranged to concentrate on the protruding region 5 on the same side (Y1 side) of the semiconductor laser device 100.

According to the first embodiment, the p-side electrode 17 (wire bonding portion 17a) and the pad electrodes 19a and 19b formed on the surface of the blue-violet semiconductor laser device 10 are formed to be aligned along the cavity direction (direction X) in a state of being insulated from each other, whereby the p-side electrode 17 (wire bonding portion 17a) and the pad electrodes 19a and 19b can be arranged to be adjacent by effectively utilizing the protruding region 5, and hence the device width of the blue-violet semiconductor laser device 10 in the direction Y can be reduced.

According to the first embodiment, the metal wire 81 is bonded to the p-side electrode 17 (wire bonding portion 17a) on the protruding region 5 of the blue-violet semiconductor laser device 10, formed with no waveguide on the lower portion, and the metal wires 82 and 83 connected to the two-wavelength semiconductor laser device 70 are bonded to the pad electrodes 19a and 19b, respectively. Thus, a plurality of the metal wires connected to the outside can be easily connected to the electrodes on the laser device side. The metal wires can be bonded on positions separated from the waveguides of the laser devices, and hence impacts to the waveguides in bonding can be reduced.

According to the first embodiment, the blue-violet semiconductor laser device 10 made of a nitride-based semiconductor is employed as the first semiconductor laser device of the present invention, and the red and infrared semiconductor laser devices 30 and 50 made of a GaAs-based semiconductor is employed as the second semiconductor laser device of the present invention. In other words, the semiconductor laser device 100 suppressing deviation of the cavity facets 10e, 30e and 50e of the respective laser devices in the cavity direction can be easily obtained, although the nitride-based semiconductor (GaN) is a harder material than the GaAs-based semiconductor and has a property inferior in cleavability.

In the manufacturing process of the semiconductor laser device 100 according to the first embodiment, the bar-shaped semiconductor laser device 100 is formed by dividing the bonded wafer-state blue-violet and two-wavelength semiconductor laser devices 10 and 70 simultaneously, whereby the wafer formed by bonding the blue-violet and two-wavelength semiconductor laser devices 10 and 70 to each other is divided along division lines (cleavage guide grooves 91 and 92) formed on both of the wafers, and hence the division surfaces (cavity facets) of a bar-shaped wafer can be linearly aligned. Thus, the cavity facets 10e, 30e and 50e constituting the respective semiconductor laser devices can be easily inhibited from deviation in the cavity direction (direction X in FIG. 13) at a step prior to division into chips. In the wafer-state two-wavelength semiconductor laser device 70 before division, the individual laser devices are continuously formed along the direction Y, and hence the division groove extending in the direction Y may be simply formed on at least a single portion. Thus, a step of forming the cleavage guide grooves 92 can be simplified.

In the manufacturing process of the semiconductor laser device 100 according to the first embodiment, the wire bonding portions 17a of the p-side electrodes 17 are exposed on the surfaces of the protruding regions 5 before bonding the wafer-state blue-violet and two-wavelength semiconductor laser devices 10 and 70 to each other, whereby no step of exposing the wire bonding portions 17a on the surface of the protruding region 5 is required after dividing the wafer into chips, and hence the manufacturing process of the semiconductor laser device 100 can be simplified.

In the manufacturing process of the semiconductor laser device 100 according to the first embodiment, the pad electrodes 19a and 19b connected to the two-wavelength semiconductor laser device 70 are aligned with the wire bonding portions 17a of the p-side electrodes 17 along the cavity direction (direction X) while holding the insulating layer 18a on the surface of the protruding region 5 before bonding the wafer-state blue-violet and two-wavelength semiconductor laser devices 10 and 70, whereby no step of forming the pad electrodes 19a and 19b on individual chips is required after dividing the wafer into chips, and hence the manufacturing process of the semiconductor laser device 100 is not complicated and can be further simplified.

In the manufacturing process of the semiconductor laser device 100 according to the first embodiment, the protective films 2a and 2b are formed on the respective cleavage planes (cavity facets 10e, 30e and 50e) of the bar-shaped wafer before dividing it into chips, whereby the wafer formed by bonding the blue-violet and two-wavelength semiconductor laser devices 10 and 70 to each other is formed with the protective film 2a (2b) on the cavity facets 10e, 30e and 50e in a state where the wafer has a substantially uniform thickness while p-side electrodes 17 are not exposed. Thus, a disadvantage that the wire bonding portions 17a are insulated by the protective film 2a (2b) extending toward and covering the surfaces of the exposed p-side electrodes 17 does not occur dissimilarly to a case where the p-side electrodes (wire bonding portions 17a) and the like of the blue-violet semiconductor laser device 10 are exposed to the outside before forming the protective film 2a (2b), for example, and hence the metal wire 81 bonded after division into chips and the wire bonding portion 17a can be reliably electrically connected (wire-bonded).

In the manufacturing process of the semiconductor laser device 100 according to the first embodiment, the division grooves 73 for forming the side surfaces 10a and 10b are formed an the bar-shaped blue-violet semiconductor laser device 10 before division into chips, and the division grooves 74 for forming the side surfaces 70a and 70b to protrude sideward from the positions formed with the side surfaces 10a and 10b are formed on the positions deviated from the positions corresponding to the division grooves 73 on the opposite surface (Z1 side) of the two-wavelength semiconductor laser device 70 to the surface bonded to the blue-violet semiconductor laser device 10. Thus, the two-wavelength semiconductor laser device 70 can be also divided on the positions formed with the division grooves 74 in response to division of the blue-violet semiconductor laser device 10 on the division grooves 73, when dividing the bar-shaped semiconductor laser device 100 to form chips. Thus, the semiconductor laser device 100 in a state where the side surfaces 70a and 70b are arranged on the positions deviated from the positions formed with the side surfaces 10a and 10b can be easily formed while dividing the bar-shaped semiconductor laser device 100 into chips.

In the manufacturing process of the semiconductor laser device 100 according to the first embodiment, the distance from the division grooves 73 corresponding to the side surfaces 10a to the division grooves 74 corresponding to the side surfaces 70a in the direction Y is equal to the distance from the division grooves 73 corresponding to the side surfaces 10b to the division grooves 74 corresponding to side surfaces 70b in the direction Y in plan view, whereby the bar-shaped wafer can be easily divided into a plurality of chips of the semiconductor laser device 100 in a state where the width of the protruding regions 5 from the side surfaces 70a to the side surfaces 10a and the width of the protruding regions 6 from the side surfaces 10b to the side surfaces 70b are equal to each other.

In the manufacturing process of the semiconductor laser device 100 according to the first embodiment, before bonding the bar-shaped blue-violet and two-wavelength semiconductor laser devices 10 and 70 to each other, the division grooves 72 are formed on the surface of the two-wavelength semiconductor laser device 70 on the side bonded to the blue-violet semiconductor laser device 10 so as to be opposed to the positions on which the division grooves 74 are supposed to be formed. Thus, in the bar-shaped two-wavelength semiconductor laser device 70, the thickness of the device substrate is reduced not only by the division grooves 74 but also by the division grooves 72, and hence the wafer can be more easily divided.

In the manufacturing process of the semiconductor laser device 100 according to the first embodiment, the design value of the cavity length L1 of the wafer-state blue-violet semiconductor laser device 10 is set to be larger than the cavity length L2 of the two-wavelength semiconductor laser device 70 having a thermal expansion coefficient larger than GaN, at the temperature T1 in alignment. Thus, both of the cavity lengths of the blue-violet semiconductor and two-wavelength semiconductor laser devices 10 and 70 can substantially coincide with each other at the bonding temperature T2, and hence the cleavage positions of both of the laser devices can be inhibited from deviating from the design positions.

In the manufacturing process of the semiconductor laser device 100 according to the first embodiment, the ridge interval P1 of the wafer-state blue-violet semiconductor laser device 10 is set to be larger than the ridge interval P2 of the two-wavelength semiconductor laser device 70 at the temperature T1. Thus, the ridge intervals of both of the blue-violet and two-wavelength semiconductor laser devices 10 and 70 can substantially coincide with each other at the bonding temperature T2, and hence a plurality of the semiconductor laser devices 100, in which the positional relation of the light-emitting points in individual chips is substantially the same, can be obtained.

In the manufacturing process of the semiconductor laser device 100 according to the first embodiment, the alignment marks 95 and 96 are formed at the same pitch as each other in each of the directions X and Y at the temperature T1, whereby alignment in bonding the wafers can be easily and precisely performed.

In the manufacturing process of the semiconductor laser device 100 according to the first embodiment, patterning of the alignment marks 96 is performed in response to patterning of the pad electrodes 19a and 19b of the blue-violet semiconductor laser device 10, whereby the alignment marks can be formed simultaneously with electrode patterns, and hence a step of forming the alignment marks can be simplified.

In the manufacturing process of the semiconductor laser device 100 according to the first embodiment, the pad electrodes 19a and 19b are patterned at the same pitches (pitches W1 and B1) as the alignment marks 96, whereby the pad electrodes and the mask patterns for forming the alignment marks are repeatedly formed at the same pitches and hence the mask can be easily prepared.

According to the first embodiment, the two-wavelength semiconductor laser device 70 is bonded to overlap on the ridge 15 of the blue-violet semiconductor laser device 10 and the ridges 35 and 55 of the red and infrared semiconductor laser devices 30 and 50 constituting the two-wavelength semiconductor laser device 70 are formed on positions overlapped with the blue-violet semiconductor laser device 10, whereby the semiconductor laser device 100 in which the ridge 15 of the blue-violet semiconductor laser device 10 does not expose from the two-wavelength semiconductor laser device 70 in the direction Y and the light-emitting points of the blue-violet and two-wavelength semiconductor laser devices 10 and 70 reliably approach each other in the direction Y can be obtained.

### Modification of First Embodiment

Referring to FIG. 11, in a manufacturing process of a semiconductor laser device 100 according to a modification of the first embodiment of the present invention, an alignment mark 96 may be formed every n laser devices along directions X and Y on a wafer of a blue-violet semiconductor laser device 10, dissimilarly to the manufacturing process of the aforementioned first embodiment. In this case, the alignment marks 96 are formed along the direction X to satisfy the relation of pitch W1=n×L1×{(1+α1×ΔT)/(1+α2×ΔT)} and formed along the direction Y to satisfy the relation of pitch B1=n×P1×{(1+α1×ΔT)/(1+α2×ΔT)}.

### Second Embodiment

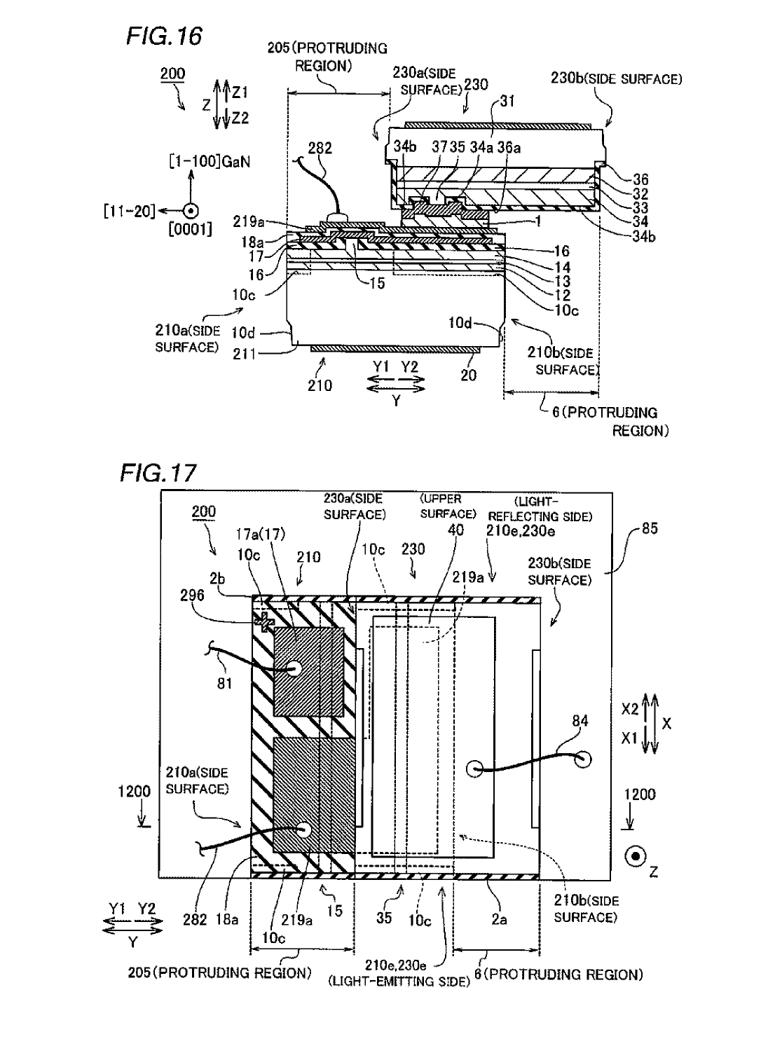

A second embodiment will be described with reference to FIGS. 16 to 18. In a semiconductor laser device 200 according to the second embodiment, only a red semiconductor laser device 230 is bonded onto a surface on a Y2 side of a blue-violet semiconductor laser device 210, and a waveguide of the blue-violet semiconductor laser device 210 is formed on a region on a Y1 side protruding sideward from the red semiconductor laser device 230, dissimilarly to the aforementioned first embodiment. The semiconductor laser device 200 is an example of the “integrated semiconductor laser device” in the present invention, and the blue-violet semiconductor laser device 210 and the red semiconductor laser device 230 are examples of the “first semiconductor laser device” and the “second semiconductor laser device” in the present invention, respectively. FIG. 16 is a sectional view taken along the line 1200-1200 in FIG. 17.

In the semiconductor laser device 200 according to the second embodiment, the red semiconductor laser device 230 is bonded onto the surface on the Y2 side of the blue-violet semiconductor laser device 210, as shown in FIG. 16.

According to the second embodiment, the devices are bonded in a state where a side surface 210a on the Y1 side of the blue-violet semiconductor laser device 210 is arranged to be deviated in a direction Y1 from a position formed with a side surface 230a on the Y1 side of the red semiconductor laser device 230 while a side surface 230b on the Y2 side of the red semiconductor laser device 230 is arranged to be deviated in a direction Y2 from a position formed with a side surface 210b on the Y2 side of the blue-violet semiconductor laser device 210. The side surfaces 210a and 210b are examples of the “first side surface” and the “second side surface” in the present invention, respectively, and the side surfaces 230a and 230b are examples of the “third side surface” and the “fourth side surface” in the present invention, respectively.

According to the second embodiment, a ridge (optical wavelength) 15 of the blue-violet semiconductor laser device 210 is formed on a protruding region 205, as shown in FIG. 17. A pad electrode 219a extending in the direction Y1 from a region bonded with the red semiconductor laser device 230 is formed on a region on the X1 and Y1 sides of an insulating layer 18a on the protruding region 205 formed with the ridge 15. The red semiconductor laser device 230 is connected to a lead terminal (not shown) through a metal wire 282 bonded to the pad electrode 219a exposed from the protruding region 205. The protruding region 205 is an example of the “first protruding region” in the present invention, and the pad electrode 219a is an example of the “second electrode” in the present invention. The metal wire 282 is an example of the “second metal wire” in the present invention.

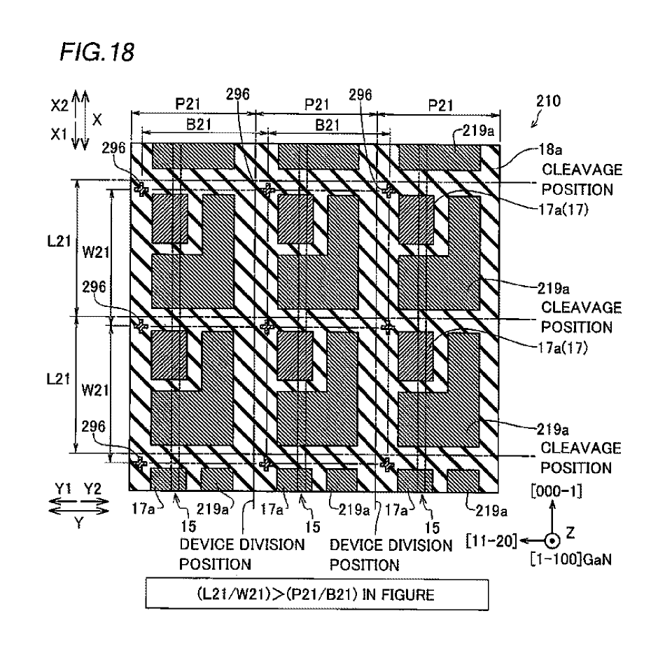

According to the second embodiment, a semiconductor device layer similar to that of the aforementioned first embodiment is stacked on an upper surface of an n-type GaN substrate 211 having a main surface formed by a (1-100) plane, thereby forming the blue-violet semiconductor laser device 210. A cavity is formed to extend along a c-axis direction. In this case, thermal expansion coefficients of GaN in an a-axis direction and the c-axis direction are about 5.0×10⁻⁶/K and about 4.5×10⁻⁶/K, respectively, and hence a thermal expansion coefficient in a substrate plane of the n-type GaN substrate 211 is anisotropic. Therefore, difference between the thermal expansion coefficients of the GaAs substrate and the GaN substrate in the a-axis direction is smaller than difference between the thermal expansion coefficients of the GaAs substrate and the GaN substrate in the c-axis direction. In order to conform pitches (W21 and B21) of alignment marks 296 of the wafer of the blue-violet semiconductor laser device 210 to pitches of alignment marks of the wafer of the red semiconductor laser device 230 at a temperature T1 and conform device pitches (cavity length L21 and a ridge pitch P21) of the wafer of the blue-violet semiconductor laser device 210 to pitches (cavity length in the direction X and a waveguide pitch in the direction Y) of the wafer of the red semiconductor laser device 230 at a bonding temperature T2, the ratio of the device pitch and the alignment mark pitch (ratio of the L21 and the W21) in a direction where the difference of the thermal expansion coefficients is larger is set to be larger than the ratio of the device pitch and the alignment mark pitch (ratio of the P21 and the B21) in a direction where the difference of the thermal expansion coefficients is smaller (L21/W21>P21/B21), as shown in FIG. 18.

The remaining structure and manufacturing process of the semiconductor laser device 200 according to the second embodiment are similar to those of the aforementioned first embodiment.

According to the second embodiment, as hereinabove described, the ridge 15 of the blue-violet semiconductor laser device 210 is formed on the protruding region 205, whereby damage to the ridge 15 in bonding the red semiconductor laser device 230 to the surface of the blue-violet semiconductor laser device 210 can be suppressed and deterioration of electric characteristics on the p-side electrode 17 side can be suppressed. The effects of the second embodiment are also similar to those of the aforementioned first embodiment.

### Third Embodiment

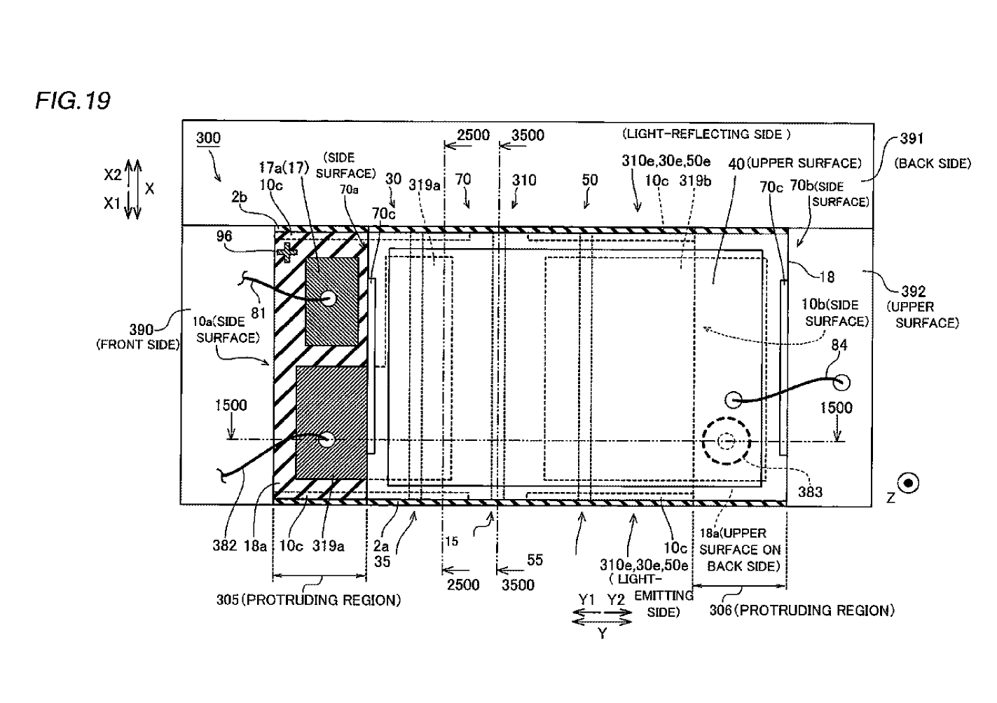

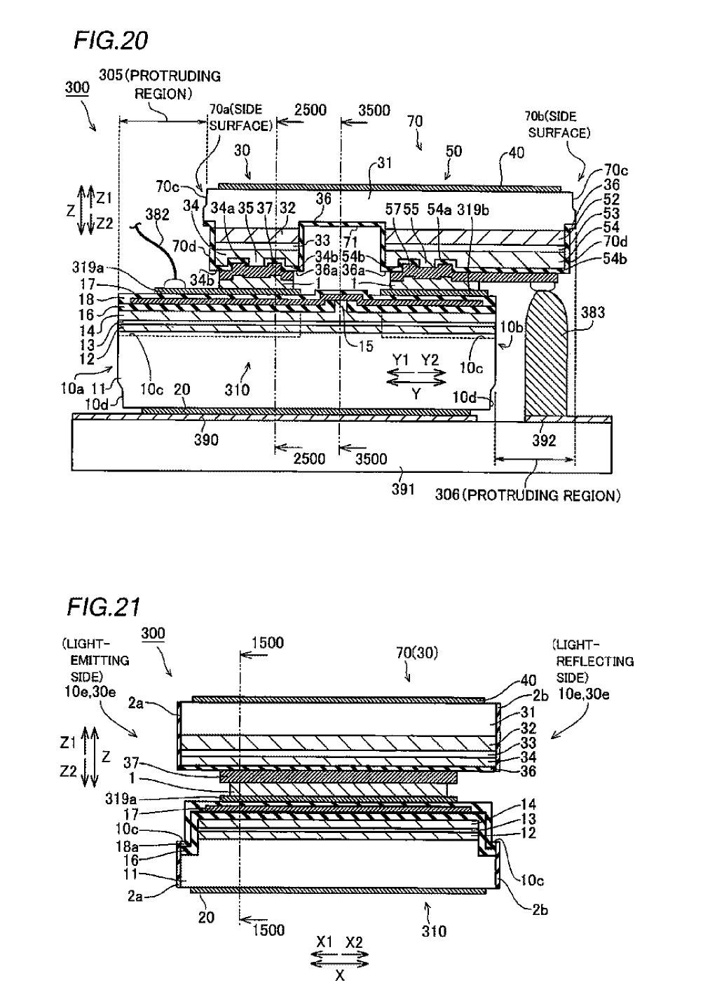

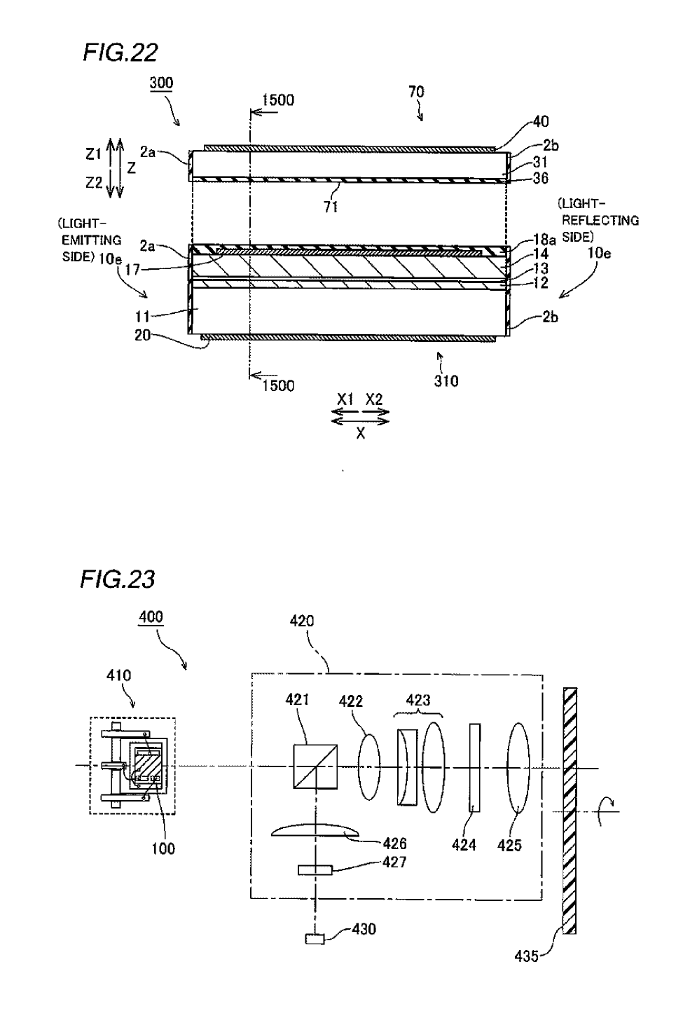

A third embodiment will be described with reference to FIGS. 19 to 22. In a semiconductor laser device 300 according to the third embodiment, only a red semiconductor laser device 30 of a bonded two-wavelength semiconductor laser device 70 is wire-bonded through a pad electrode 319a provided on a protruding region 305 of a blue-violet semiconductor laser device 310, and a pad electrode of an infrared semiconductor laser device 50 is formed to extend to a protruding region 306 of the two-wavelength semiconductor laser device 70. The semiconductor laser device 300 is an example of the “integrated semiconductor laser device” in the present invention, and the protruding regions 305 and 306 are examples of the “first protruding region” and the “second protruding region” in the present invention, respectively. The blue-violet semiconductor laser device 310 and the pad electrode 319a are examples of the “first semiconductor laser device” and the “second semiconductor laser device” in the present invention, respectively. FIG. 20 is a sectional view taken along the line 1500-1500 in FIG. 19, and FIG. 21 is a sectional view taken along the line 2500-2500 in FIG. 19. FIG. 22 is a sectional view taken along the line 3500-3500 in FIG. 19.

According to the third embodiment, the substantially L-shaped pad electrode 319a extending in a direction Y1 from a region bonded with the red semiconductor laser device 30 is formed on a region on a X1 side of an insulating layer 18a on the protruding region 305, as shown in FIG. 19. The red semiconductor laser device 30 is connected to the lead terminal through a metal wire 382 bonded to the pad electrode 319a exposed from the protruding region 305. The pad electrode 319a is an example of the “second electrode” in the present invention, the metal wire 382 is an example of the “second metal wire” in the present invention. In the blue-violet semiconductor laser device 310, an n-side electrode 20 is fixed to a submount 391 through a pad electrode 390.

On the other hand, a rectangular pad electrode 319b (shown by broken lines) is formed on an upper surface on a Y2 side of the insulating layer 18a. The infrared semiconductor laser device 50 is connected to a pad electrode 392 on the submount 391 through a bump 383 formed on a lower surface a p-side electrode 57 on the protruding region 306, as shown in FIG. 20. In FIG. 19, an n-side electrode 40 (shown by a solid line) in the uppermost part is not hatched in order to show the shapes of the pad electrodes 319a and 319b hiding behind the two-wavelength semiconductor laser device 70 for convenience sake.

In a section shown in FIG. 21 (section taken along the line 2500-2500 in FIG. 20), the pad electrode 319a extending in the direction X is bonded to a p-side electrode 37 of the red semiconductor laser device 30 through a fusion layer 1. In a section shown in FIG. 22 (section taken along the line 3500-3500 in FIG. 20), a p-side electrode 17 of the blue-violet semiconductor laser device 310 is opposed, at a prescribed interval in a direction Z, to an insulating layer 36 formed on the groove 71 of the two-wavelength semiconductor laser device 70 in a state of being completely covered by the insulating layer 18a along the direction X.

The remaining structure and manufacturing process of the semiconductor laser device 300 according to the third embodiment are similar to those of the aforementioned first embodiment.

According to the third embodiment, as hereinabove described, the pad electrode 319b of the infrared semiconductor laser device 50 is formed to extend to the protruding region 306, whereby the pad electrode 319b of the infrared semiconductor laser device 50 can be connected to the pad electrode 392 on the submount 391 through the bump 383 by effectively utilizing the protruding region 306 formed on the Y2 side instead of the protruding region 305. The effects of the third embodiment are also similar to those of the aforementioned first embodiment.

### Fourth Embodiment

An optical pickup 400 according to a fourth embodiment of the present invention will be described with reference to FIG. 6 and FIGS. 23 to 25. The optical pickup 400 is an example of the “optical apparatus” in the present invention.

The optical pickup 400 according to the fourth embodiment of the present invention comprises a semiconductor laser apparatus 410 mounted with the semiconductor laser device 100 according to the aforementioned first embodiment, an optical system 420 adjusting a laser beam emitted from the semiconductor laser apparatus 410, and a light detection portion 430 receiving the laser beam, as shown in FIG. 23.

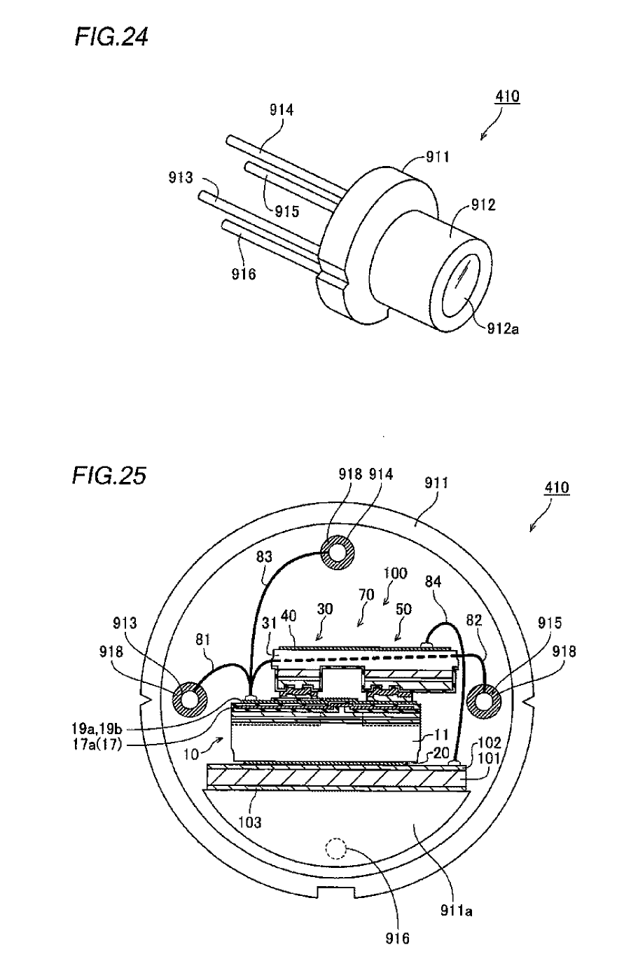

The semiconductor laser apparatus 410 has a base 911 made of a conductive material, a cap 912 arranged on a front surface of the base 911, leads 913, 914, 915 and 916 mounted on a rear surface of the base 911, as shown in FIGS. 24 and 25. The header 911a is integrally formed with the base 911 on the front surface of the base 911. The semiconductor laser device 100 is arranged on an upper surface of the header 911a, and a submount 101 made of a conductive material such as Cu and the header 911a are fixed by a bonding layer 103 made of Au—Sn solder. An optical window 912a transmitting a laser beam emitted from the semiconductor laser device 100 is mounted on a front surface of the cap 912, and the semiconductor laser device 100 inside the base 911 covered with the cap 912 is sealed by the cap 912.

As shown in FIG. 25, the leads 913 to 915 pass through the base 911 and fixed to be electrically insulated from each other through insulating members 918. As shown in FIG. 6, the lead 913 is electrically connected to a wire-bonding portion 17a of a pad electrode 17 through a metal wire 81, and the lead 915 is electrically connected to a pad electrode 19a through a metal wire 82. The lead 914 is electrically connected to a pad electrode 19b through a metal wire 83. An n-side electrode 40 and a connecting electrode 102 on the submount 101 are electrically connected through a metal wire 84. The lead 916 is integrally formed with the base 911. Thus, the lead 916 and an n-side electrode 20 of the blue-violet semiconductor laser device 10 and the n-side electrodes 40 of the red and infrared semiconductor laser devices 30 and are electrically connected, and cathode common connection of the blue-violet, red and infrared semiconductor laser devices 10, 30 and 50 is achieved.

The optical system 420 has a polarizing beam splitter (PBS) 421, a collimator lens 422, a beam expander 423, a λ/4 plate 424, an objective lens 425, a cylindrical lens 426 and an optical axis correction device 427, as shown in FIG. 23.

The PBS 421 totally transmits the laser beam emitted from the semiconductor laser device 410 and totally reflects the laser beam returned from an optical disc 435. The collimator lens 422 converts the laser beam from the semiconductor laser device 100 transmitting through the PBS 421 to parallel light. The beam expander 423 includes a concave lens, a convex lens and an actuator (not shown). The actuator has a function of correcting a state of wavefront of the laser beam emitted from the semiconductor laser apparatus 410 by changing a distance of the concave lens and the convex lens in response to a servo signal from the servo circuit described later.

The λ/4 plate 424 converts a linearly-polarized laser beam converted to substantially parallel light by the collimator lens 422 to circularly-polarized light. The λ/4 plate 424 converts the circularly-polarized laser beam returned from the optical disc 435 to linearly-polarized light. A direction of polarization of linearly-polarized light in this case is perpendicular to a direction of linear polarization of the laser beam emitted from the semiconductor laser apparatus 410. Thus, the laser beam returned from the optical disc 435 is totally reflected by the PBS 421. The objective lens 425 converges the laser beam transmitted through the λ/4 plate 424 on a surface (recording layer) of the optical disc 435. The objective lens 425 is movable in a focus direction, a tracking direction and a tilt direction in response to a servo signal (a tracking servo signal, a focus servo signal and a tilt servo signal) from the servo circuit described later by an objective lens actuator (not shown).

The cylindrical lens 426, optical axis correction device 427 and the light detection portion 430 are arranged along an optical axis of the laser beam totally reflected by the PBS 421. The cylindrical lens 426 gives astigmatic action to an incident laser beam. The optical axis correction device 427 is formed by diffraction grating and so arranged that a spot of zero-order diffracted light of each of blue-violet, red and infrared laser beams transmitted through the cylindrical lens 426 coincides on a detection region of the light detection portion 430 described later.

The light detection portion 430 outputs a playback signal on the basis of intensity distribution of a received laser beam. The light detection portion 430 has a prescribed patterned detection region to obtain the playback signal as well as a focus error signal, a tracking error signal and a tilt error signal. Thus, the optical pickup 400 comprising the semiconductor laser apparatus 410 is formed.

In this optical pickup 400, the semiconductor laser apparatus 410 is so formed that blue-violet, red and infrared laser beams independently emit from the blue-violet, red and infrared semiconductor laser devices 10, 30 and 50 by independently applying voltages between the lead 916 and the leads 913 to 915, respectively. As hereinabove described, the laser beams emitted from the semiconductor laser apparatus 410 are adjusted by the PBS 421, the collimator lens 422, the beam expander 423, the λ/4 plate 424, the objective lens 425, the cylindrical lens 426 and the optical axis correction device 427, and thereafter irradiated on the detection region of the light detection portion 430.

When data recorded in the optical disc 435 is playback, the laser beams are applied to the recording layer of the optical disc 435 while controlling respective laser power emitted from the blue-violet, red and infrared semiconductor laser devices 10, 30 and 50 to be constant and the playback signal output from the light detection portion 430 can be obtained. The actuator of the beam expander 423 and the objective lens actuator driving the objective lens 425 can be feedback-controlled by the focus error signal, the tracking error signal and the tilt error signal simultaneously output.

When data is recorded in the optical disc 435, the laser beams are applied to the optical disc 435 while controlling laser power emitted from any one of the blue-violet, red and infrared semiconductor laser devices 10, 30 and 50 on the basis of data to be recorded. Thus, the data can be recorded in the recording layer of the optical disc 435. Similarly to the above, the actuator of the beam expander 423 and the objective lens actuator driving the objective lens 425 can be feedback-controlled by the focus error signal, the tracking error signal and the tilt error signal output from the light detection portion 430.

Thus, record in the optical disc 435 and playback can be performed with the optical pickup 400 comprising the semiconductor laser apparatus 410.

In the optical pickup 400 according to the fourth embodiment, the semiconductor laser device 100 is mounted in the semiconductor laser apparatus 410, and hence the optical pickup 400 comprising the semiconductor laser device 100 in which the yield is improved and the manufacturing process is simplified can be easily obtained.

### Fifth Embodiment

An optical disc apparatus 500 according to a fifth embodiment of the present invention will be described with reference to FIGS. 6, 23 and 26.

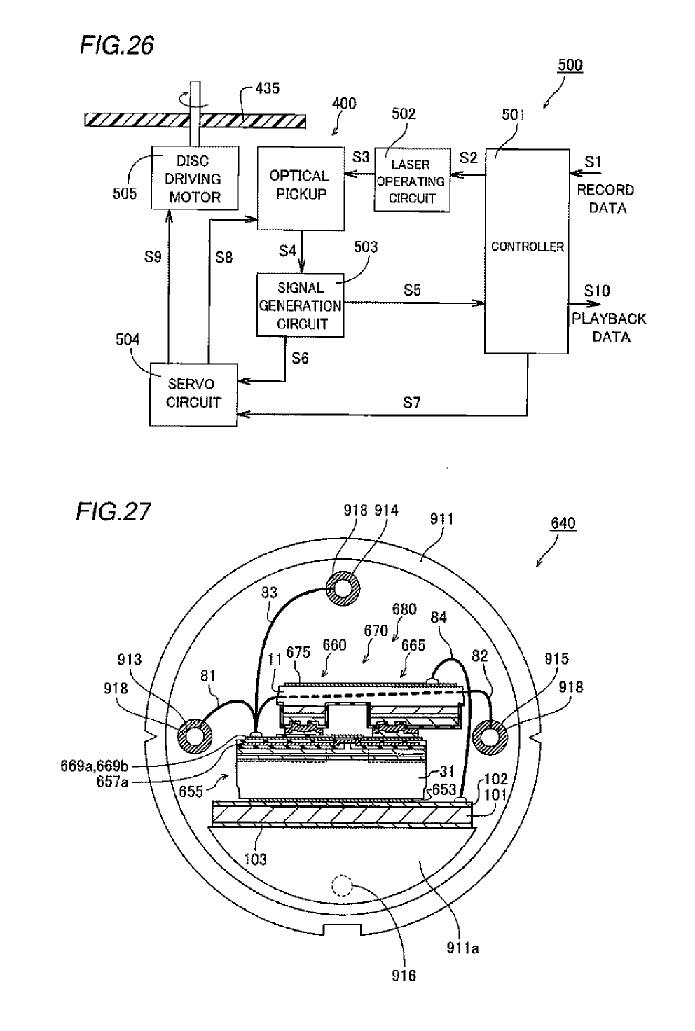

The optical disc apparatus 500 according to the fifth embodiment of the present invention comprises the optical pickup 400 according to the aforementioned fourth embodiment, a controller 501, a laser operating circuit 502, a signal generation circuit 503, a servo circuit 504 and a disc driving motor 505, as shown in FIG. 26. The optical disc apparatus 500 is an example of the “optical apparatus” in the present invention.

Recorded data S1 generated on the basis of data to be recorded in the optical disc 435 is inputted in the controller 501. The controller 501 outputs a signal 52 to the laser operating circuit 502 and outputs a signal S7 to the servo circuit 504 in response to the record data 51 and a signal S5 from the signal generation circuit 503 described later. The controller 501 outputs playback data S10 on the basis of the signal S5, as described later. The laser operating circuit 502 outputs a signal S3 controlling laser power emitted from the semiconductor laser apparatus 410 in the optical pickup 400 in response to the aforementioned signal S2. In other words, the semiconductor laser apparatus 410 is formed to be driven by the controller 501 and the laser operating circuit 502.

In the optical pickup 400, a laser beam controlled in response to the aforementioned signal S3 is applied to the optical disc 435, as show in FIG. 26. A signal S4 is output from the light detection portion 430 in the optical pickup 400 to the signal generation circuit 503. The optical system 420 (the actuator of the beam expander 423 and the objective lens actuator driving the objective lens 425) in the optical pickup 400 is controlled by a servo signal S8 from the servo circuit 504 described later. The signal generation circuit 503 performs amplification and arithmetic processing for the signal S4 output from the optical pickup 400, to output the first output signal S5 including a playback signal to the controller 501 and to output a second output signal S6 performing the aforementioned feed-back control of the optical pickup 400 and rotational control, described later, of the optical disc 435 to the servo circuit 504.

As shown in FIG. 26, the servo circuit 504 outputs the servo signal S8 controlling the optical system 420 in the optical pickup 400 and a motor servo signal 59 controlling the disc driving motor 505 in response to the second output signal S6 and the signal S7 from the signal generation circuit 503 and the controller 501. The disc driving motor 505 controls a rotational speed of the optical disc 435 in response to the motor servo signal S9.

When data recorded in the optical disc 435 is playback, a laser beam having a wavelength to be applied is first selected by means identifying types (CD, DVD, BD, etc.) of the optical disc 435 which is not described here. Then, the signal S2 is so output from the controller 501 to the laser operating circuit 502 that an intensity of the laser beam having the wavelength to be emitted from the semiconductor laser apparatus 410 in the optical pickup 400 is constant. Further, the signal S4 including a playback signal is output from the light detection portion 430 to the signal generation circuit 503 by functioning the semiconductor laser apparatus 410, the optical system 420 and the light detection portion 430 of the optical pickup 400 described above, and the signal generation circuit 503 outputs the signal S5 including the playback signal to the controller 501. The controller 501 processes the signal S5, so that the playback signal recorded in the optical disc 435 is extracted and output as the reproduction data S10. Information such as images and sound recorded in the optical disc 435 can be output to a monitor, a speaker and the like with this playback data S10, for example. Feed-back control of each portion is performed on the basis of the signal S4 from the light detection portion 430.

When data is recorded in the optical disc 435, the laser beam having the wavelength to be applied is selected by the means identifying types of the optical disc 435, similarly to the above. Then, the signal S2 is output from the controller 501 to the laser operating circuit 502 in response to the record data S1 responsive to recorded data. Further, data is recorded in the optical disc 435 by functioning the semiconductor laser apparatus 410, the optical system 420 and the light detection portion 430 of the optical pickup 400 described above, and feed-back control of each portion is performed on the basis of the signal S4 from the light detection portion 430.

Thus, record in the optical disc 435 and playback can be performed with the optical disc apparatus 500.

In the optical disc apparatus 500 according to the fifth embodiment, the semiconductor laser device 100 (see FIG. 23) is mounted in the semiconductor laser apparatus 410, and hence the optical disc apparatus 500 comprising the semiconductor laser device 100 in which the yield is improved and the manufacturing process is simplified can be easily obtained. The remaining effects of the fifth embodiment are similar to those of the aforementioned fourth embodiment.

### Sixth Embodiment

A structure of a projector 600 according to a sixth embodiment of the present invention will be described with reference to FIGS. 1, 6, 27 and 28. In the projector 600, each of semiconductor laser devices constituting a semiconductor laser apparatus 640 is substantially simultaneously turned on. The projector 600 is an example of the “optical apparatus” in the present invention.

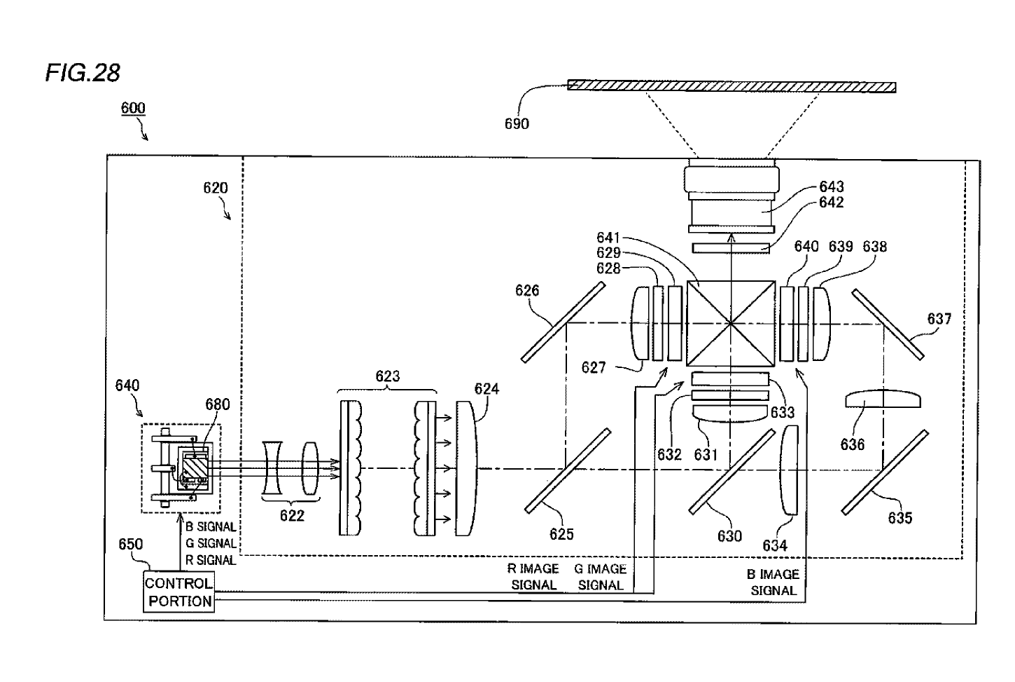

The projector 600 according to the sixth embodiment of the present invention comprises the semiconductor laser apparatus 640, an optical system 620 consisting of a plurality of optical components and a control portion 650 controlling the semiconductor laser apparatus 640 and the optical system 620, as shown in FIG. 28. Thus, laser beams emitted from the semiconductor laser apparatus 640 are modulated by the optical system 620 and thereafter projected on an external screen 690 or the like.

As shown in FIG. 27, the semiconductor laser apparatus 640 comprises an RGB three-wavelength semiconductor laser device 680 formed by bonding a red semiconductor laser device 655 having a lasing wavelength of about 655 nm of red (R) onto a two-wavelength semiconductor laser device 670 monolithically formed with a green semiconductor laser device 660 having a lasing wavelength of about 530 nm of green (G) and a blue semiconductor laser device 665 having a lasing wavelength of about 480 nm of blue (B), and capable of emitting laser beams of three-wavelengths of RGB.

The RGB three-wavelength semiconductor laser device 680 comprises the red semiconductor laser device 655 formed on an upper surface of an n-type GaAs substrate 31 instead of the blue-violet semiconductor laser device 10, and the two-wavelength semiconductor laser device 670 monolithically formed with the green and the blue semiconductor laser devices 660 and 665 on a lower surface of an n-type GaN substrate 11 instead of the two-wavelength semiconductor laser device 70 monolithically formed with the red and infrared semiconductor laser devices 30 and 50, with reference to the semiconductor laser device 100 of the first embodiment shown in FIG. 1. The RGB three-wavelength semiconductor laser device 680 is an example of the “integrated semiconductor laser device” in the present invention.

In the RGB three-wavelength semiconductor laser device 680, an n-side electrode 653 is electrically connected and fixed to a connecting layer 102 formed on an upper surface of a submount 101 through Au—Sn solder (not shown). The red semiconductor laser device 655 is an example of the “first semiconductor laser device” in the present invention, and the two-wavelength semiconductor laser device 670 constituted by the green and blue semiconductor laser devices 660 and 665 is an example of the “second semiconductor laser device” in the present invention. The remaining structure and manufacturing process of the RGB three-wavelength semiconductor laser device 680 are similar to those of the semiconductor laser device 100 of the aforementioned first embodiment.

A lead 913 is electrically connected to a wire-bonding portion 657a conducting with a p-type semiconductor layer of the red semiconductor laser device 655 through a metal wire 81, and a lead 915 is electrically connected to a pad electrode 669b conducting with a p-type semiconductor layer of the green semiconductor laser device 660 through a metal wire 82. A lead 914 is electrically connected to a pad electrode 669b conducting with a p-type semiconductor layer of the blue semiconductor laser device 665 through a metal wire 83. An n-side electrode 675 of the two-wavelength semiconductor laser device 670 and the connecting electrode 102 on the submount 101 are electrically connected through a metal wire 84. Thus, a lead 916 and the n-side electrode 653 of the red semiconductor laser device 655 as well as the lead 916 and the n-side electrode 675 of the two-wavelength semiconductor laser device 670 are electrically connected, and cathode common connection of the red and two-wavelength semiconductor laser devices 655 and 670 is achieved. The wire-bonding portion 657a and the pad electrodes 669a and 669b are provided on a surface of the red semiconductor laser device 655 in a state of having the positional relation corresponding to the wire bonding portion 17a and the pad electrodes 19a and 19b shown in FIG. 6, respectively. The wire-bonding portion 657a is an example of the “first electrode” in the present invention, and the pad electrodes 669a and 669b are each an example of the “second electrode” in the present invention.

In the optical system 620, the laser beams emitted from the semiconductor laser apparatus 640 are converted to parallel beams having prescribed beam diameters by a dispersion angle control lens 622 consisting of a concave lens and a convex lens, and thereafter introduced into a fly-eye integrator 623, as shown in FIG. 26. The fly-eye integrator 623 is so formed that two fly-eye lenses consisting of fly-eye lens groups face each other, and provides a lens function to the beams introduced from the dispersion angle control lens 622 so that light quantity distributions in incidence upon liquid crystal panels 629, 633 and 640 are uniform. In other words, the beams transmitted through the fly-eye integrator 623 are so adjusted that the same can be incident upon the liquid crystal panels 629, 633 and 640 with spreads of aspect ratios (16:9, for example) corresponding to the sizes of the liquid crystal panels 629, 633 and 640.

The beams transmitted through the fly-eye integrator 623 are condensed by a condenser lens 624. In the beams transmitted through the condenser lens 624, only the red beam is reflected by a dichroic mirror 625, while the green and blue beams are transmitted through the dichroic mirror 625.

The red beam is parallelized by a lens 627 through a mirror 626, and thereafter incident upon the liquid crystal panel 629 through an incidence-side polarizing plate 628. The liquid crystal panel 629 is driven in response to a red image signal (R image signal), thereby modulating the red beam.

In the beams transmitted through a dichroic mirror 625, only the green beam is reflected by the dichroic mirror 630, while the blue beam is transmitted through the dichroic mirror 630.

The green beam is parallelized by a lens 631, and thereafter incident upon the liquid crystal panel 633 through an incidence-side polarizing plate 632. The liquid crystal panel 633 is driven in response to a green image signal (G image signal), thereby modulating the green beam.

The blue beam transmitted through the dichroic mirror 630 passes through a lens 634, a mirror 635, a lens 636 and a mirror 637, is parallelized by a lens 638, and thereafter incident upon the liquid crystal panel 640 through an incidence-side polarizing plate 639. The liquid crystal panel 640 is driven in response to a blue image signal (B image signal), thereby modulating the blue beam.

Thereafter the red, green and blue beams modulated by the liquid crystal panels 629, 633 and 640 are synthesized by a dichroic prism 641, and thereafter introduced into a projection lens 643 through an emission-side polarizing plate 642. The projection lens 643 stores a lens group for imaging projected light on a projected surface (screen 690) and an actuator for adjusting the zoom and the focus of the projected image by partially displacing the lens group in an optical axis direction.

In the projector 600, the control portion 650 controls to supply stationary voltages as an R signal related to driving of the red semiconductor laser device 655, a G signal related to driving of the green semiconductor laser device 660 and a B signal related to driving of the blue semiconductor laser device 665 to the respective laser devices of the semiconductor laser apparatus 640. Thus, the red, green and blue semiconductor laser devices 655, 660 and 665 of the semiconductor laser apparatus 640 are substantially simultaneously driven. The control portion 650 is formed to control the intensities of the beams emitted from the red, green and blue semiconductor laser devices 655, 660 and 665 of the semiconductor laser apparatus 640, thereby controlling the hue, brightness etc. of pixels projected on the screen 690. Thus, the control portion 650 projects a desired image on the screen 690.

The projector 600 loaded with the semiconductor laser apparatus 640 according to the first embodiment of the present invention is constituted in the aforementioned manner.

### Seventh Embodiment

A structure of a projector 700 according to a seventh embodiment of the present invention will be described with reference to FIGS. 27, 29 and 30. In the projector 700, each of semiconductor laser devices constituting a semiconductor laser apparatus 640 is turned on in a time-series manner. The projector 700 is an example of the “optical apparatus” in the present invention.

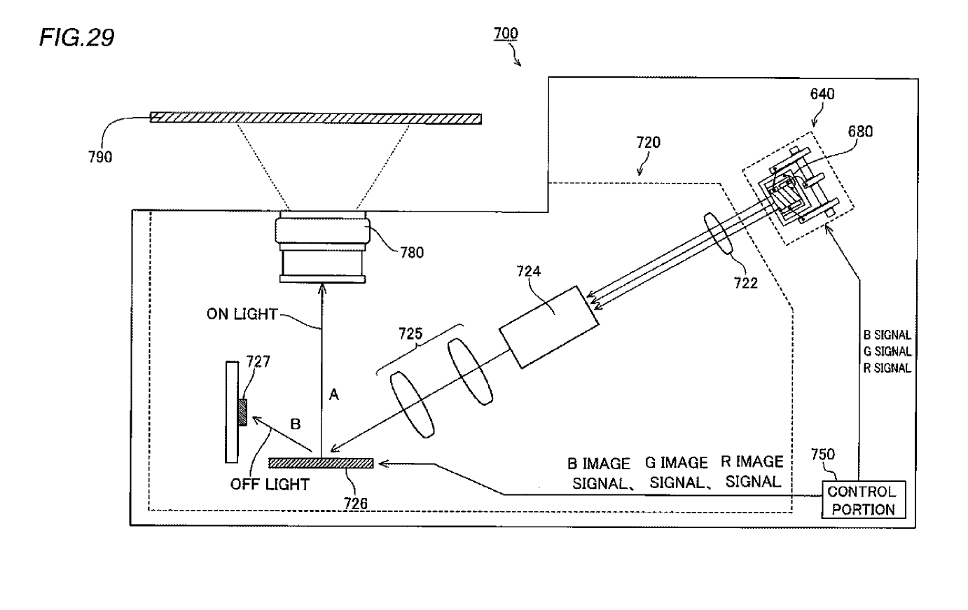

The projector 700 according to the seventh embodiment of the present invention comprises the semiconductor laser apparatus 640 employed in the aforementioned sixth embodiment, an optical system 720, and a control portion 750 controlling the semiconductor laser apparatus 640 and the optical system 720, as shown in FIG. 29. Thus, laser beams emitted from the semiconductor laser apparatus 640 are modulated by the optical system 720 and thereafter projected on a screen 790 or the like.

In the optical system 720, the laser beams emitted from the semiconductor laser apparatus 640 are converted to parallel beams by a lens 722, and thereafter introduced into a light pipe 724.

The light pipe 724 has a specular inner surface, and the laser beams are repeatedly reflected by the inner surface of the light pipe 724 to travel in the light pipe 724. At this time, intensity distributions of the laser beams of respective colors emitted from the light pipe 724 are uniformized due to multiple reflection in the light pipe 724. The laser beams emitted from the light pipe 724 are introduced into a digital micromirror device (DMD) 726 through a relay optical system 725.

The DMD 726 consists of a group of small mirrors arranged in the form of a matrix. The DMD 726 has a function of expressing (modulating) gradation of each pixel by switching a direction of reflection of light on each pixel position between a first direction A toward a projection lens 780 and a second direction B deviating from the projection lens 780. Light (ON-light) incident upon each pixel position and reflected in the first direction A is introduced into the projection lens 780 and projected on a projected surface (screen 790). On the other hand, light (OFF-light) reflected by the DMD 726 in the second direction B is not introduced into the projection lens 780 but absorbed by a light absorber 727.

In the projector 700, the control portion 750 controls to supply a pulse voltage to the semiconductor laser apparatus 640, thereby dividing the red, green and blue semiconductor laser devices 655, 660 and 665 of the semiconductor laser apparatus 640 in a time-series manner and cyclically driving the same one by one. Further, the control portion 750 is so formed that the DMD 726 of the optical system 720 modulates light in response to the gradations of the respective pixels (R, G and B) in synchronization with the driving of the red, green and blue semiconductor laser devices 655, 660 and 665.

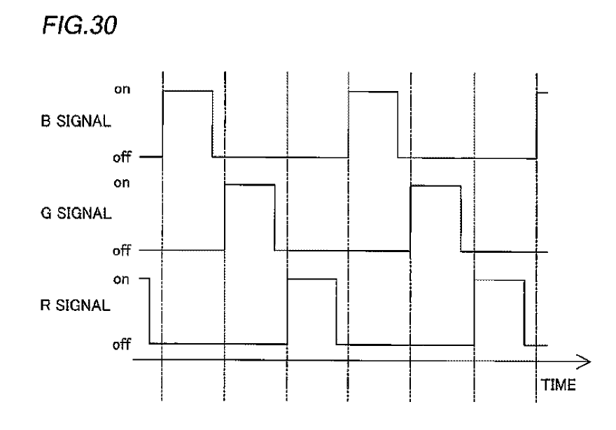

More specifically, an R signal related to driving of the red semiconductor laser device 655 (see FIG. 27), a G signal related to driving of the green semiconductor laser device 660 (see FIG. 27) and a B signal related to driving of the blue semiconductor laser device 665 (see FIG. 27) are divided in a time-series manner not to overlap with each other and supplied to the respective laser devices of the semiconductor laser apparatus 640 by the control portion 750 (see FIG. 29), as shown in FIG. 30. In synchronization with the B, G and R signals, the control portion 750 outputs a B image signal, a G image signal and an R image signal to the DMD 726.

Thus, the blue semiconductor laser device 665 emits a blue beam on the basis of the B signal in a timing chart shown in FIG. 30, while the DMD 726 modulates the blue beam at this timing on the basis of the B image signal. Further, the green semiconductor laser device 660 emits a green beam on the basis of the G signal output subsequently to the B signal, and the DMD 726 modulates the green beam at this timing on the basis of the G image signal. In addition, the red semiconductor laser device 655 emits a red beam on the basis of the R signal output subsequently to the G signal, and the DMD 726 modulates the red beam at this timing on the basis of the R image signal. Thereafter the blue semiconductor laser device 665 emits the blue beam on the basis of the B signal output subsequently to the R signal, and the DMD 726 modulates the blue beam again at this timing on the basis of the B image signal. The aforementioned operations are so repeated that an image formed by application of the laser beams based on the B, G and R image signals is projected on the projected surface (screen 790).

The projector 700 loaded with the semiconductor laser apparatus 640 according to the seventh embodiment of the present invention is constituted in the aforementioned manner.

Although the present invention has been described and illustrated in detail, it is clearly understood that the same is by way of illustration and example only and is not to be taken by way of limitation, the spirit and scope of the present invention being limited only by the terms of the appended claims.

For example, while the alignment marks are formed on individual laser devices before division into chips from the central portion of the wafer to the peripheral portions in the manufacturing process of each of the aforementioned first to seventh embodiments, the present invention is not restricted to this but the four alignment marks may be formed on only four corners of the peripheral portions of the wafer.

While the bar-shaped semiconductor laser device may be formed by bonding the previously formed bar-shaped first and second semiconductor laser device substrates in each of the aforementioned first to seventh embodiments. Also according to this structure, the bar-shaped semiconductor laser device may simply be formed by bonding the bar-shaped second semiconductor laser device substrate to the bar-shaped first semiconductor laser device substrate extending in a prescribed direction along this direction dissimilarly to a case where a plurality of second semiconductor laser devices previously divided in the form of chips are bonded on the surface of the bar-shaped first semiconductor laser device substrate. Thus, in the bar-shaped semiconductor laser device, the cavity facets of the second semiconductor laser device are aligned with the cavity facets of the first semiconductor laser device on the same plane, and hence the cavity facets constituting the respective laser devices can be inhibited from being deviated from each other.

While the alloying step is performed after forming the metal layer on the n-type GaAs substrate of the second semiconductor laser device in each of the aforementioned first to seventh embodiments, the present invention is not restricted to this but a metal allowing ohmic contact without the alloying step may be employed as the n-side electrode. In this case, the n-side electrode may be formed in a state where the thickness of the n-type GaAs substrate is reduced by etching (thickness of about 50 μm, for example), before forming the n-side electrodes.

While the devices are bonded in a state where the light-emitting points of the first semiconductor laser device and the light-emitting points of the second semiconductor laser device are deviated from each other in a device-thickness direction (in the direction Z of FIG. 1) in each of the aforementioned first to seventh embodiments, the present invention is not restricted to this but the light-emitting points of the first semiconductor laser device and the light-emitting points of the second semiconductor laser device may be substantially linearly aligned in a lateral direction (direction Y).

While the cleavage guide grooves 91 (92) for cleaving the wafer in the form of a bar or the division grooves 73 (74) for dividing the device into chips are formed by etching or with the diamond point in each of the aforementioned first to seventh embodiments, the present invention is not restricted to this but the aforementioned grooves may be formed by laser-beam irradiation.

While the insulating films or the p-side electrodes are formed after forming the cleavage guide grooves 91 so that the wafer-state first semiconductor laser device is formed in each of the aforementioned first to seventh embodiments, the present invention is not restricted to this but the cleavage guide grooves 91 may be formed after forming the insulating films or the p-side electrodes. In other words, the cleavage guide grooves 91 may simply be formed before the step of bonding the wafers.

While the fusion layers 1 are made of Au—Sn solder in each of the aforementioned first to seventh embodiments, the present invention is not restricted to this but the fusion layers may be made of solder materials such as Au, Sn, In, Pb, Ge, Ag, Cu or Si or alloy materials thereof. Alternatively, other bonding method not employing solder may be employed.

While the n-type GaN substrate and the n-type GaAs substrate are employed as a substrate in each of the aforementioned first to seventh embodiments, the present invention is not restricted to this but other substrate such as a GaP substrate and an Si substrate may be employed.

While the division grooves 72 and the groove 71 of the n-type GaAs substrate 31 are formed to have substantially the same depth in each of the aforementioned first to seventh embodiments, the present invention is not restricted to this but depths of the division grooves and the groove may be different.

The cavity of the blue-violet semiconductor laser device 210 may be formed to extend in the a-axis direction having a larger thermal expansion coefficient in the aforementioned second embodiment. In this case, it may simply be set to satisfy the relation of L21/W21<P21/B21.

A nonpolar plane or a semipolar plane such as (11-2±2) plane or (1-10±1) plane may be employed as the main surface of the GaN substrate of the blue-violet semiconductor laser device 210 in the aforementioned second embodiment.

While a single-wavelength semiconductor laser device is employed as the “first semiconductor laser device” in the present invention in each of the aforementioned first to seventh embodiments, the present invention is not restricted to this but the two-wavelength semiconductor laser device may be employed as the first semiconductor laser device. For example, a RGB three-wavelength semiconductor laser device is so formed that a two-wavelength semiconductor laser device monolithically formed with blue and green semiconductor laser devices are formed on a Gail substrate can be employed as the first semiconductor laser device while a red semiconductor laser device formed on a GaAs substrate can be employed as the “second semiconductor laser device” in the present invention. In this case, the GaN substrate side of the two-wavelength semiconductor laser device can be bonded to a submount, and hence heat radiation of the semiconductor laser device is favorable as compared with a case of bonding the GaAs substrate to the submount. Therefore, heat radiation of the RGB three-wavelength semiconductor laser device of the aforementioned modification is improved in comparison with the RGB three-wavelength semiconductor laser device 680 employed in each of the aforementioned sixth and seventh embodiments, and hence operating characteristics of the projector can be improved.

The width of the protruding region may be smaller than the width of the portion where the first and second semiconductor laser devices overlap with each other. In this case, the integrated semiconductor laser device can be inhibited from being inclined with respect to the submount when the integrated semiconductor laser device is mounted on the submount.

The width of the portion where the first and second semiconductor laser devices overlap with each other may be smaller than the width of the protruding region. In this case, the width of the integrated semiconductor laser device can be further reduced.

While the integrated semiconductor laser device is so formed that the waveguide of the “second semiconductor laser device” of the present invention does not overlap on the wavelength of the “first semiconductor laser device” of the present invention in each of the aforementioned first to seventh embodiment, the present invention is not restricted to this but the integrated semiconductor laser device is more preferably so formed that the waveguide of the “second semiconductor laser device” overlap on the wavelength of the “first semiconductor laser device.

What is claimed is:

1. A method of manufacturing an integrated semiconductor laser device formed by bonding a first semiconductor laser device and a second semiconductor laser device, comprising steps of:
forming a third oblong substrate by bonding a first oblong substrate formed with a plurality of said first semiconductor laser devices and a second oblong substrate formed with a plurality of said second semiconductor laser devices; and
dividing said third oblong substrate so that first side surfaces of said first semiconductor laser devices having said first side surfaces and second side surfaces protrude from positions formed with third side surfaces of said second semiconductor laser devices having said third side surfaces and fourth side surfaces while said fourth side surfaces opposite to said third side surfaces protrude from said second side surfaces opposite to said first side surfaces, wherein
cavities of said first and second semiconductor laser devices extend along said first direction,
said first, second, third and fourth side surfaces extend along said first direction,
said first oblong substrate is so formed that a plurality of said first semiconductor laser devices are aligned along a second direction perpendicular to said first direction in an in-plane direction of said first oblong substrates, and
said second oblong substrate is so formed that a plurality of said second semiconductor laser devices are aligned along said second direction.

2. The method of manufacturing an integrated semiconductor laser device according to claim 1, wherein
said step of forming said third oblong substrate includes a step of bonding a first semiconductor laser device substrate formed with a plurality of said first semiconductor laser devices and a second semiconductor laser device substrate formed with a plurality of said second semiconductor laser devices, and a step of dividing said first and second semiconductor laser device substrates simultaneously in a state where said first and second semiconductor laser device substrates are bonded to each other.

3. The method of manufacturing an integrated semiconductor laser device according to claim 1, wherein
said integrated semiconductor laser device is so formed that a first surface of said first semiconductor laser device and said second semiconductor laser device are bonded to each other and a first protruding region on said first surface between said first and third side surface is exposed from said second semiconductor laser device,
further comprising a step of forming first electrodes on said first protruding regions in advance of said step of forming said third oblong substrate, wherein
said first electrodes are exposed from said second semiconductor laser devices in said step of dividing said third oblong substrate.

4. The method of manufacturing an integrated semiconductor laser device according to claim 1, wherein
said first and second oblong substrates have cavity facets,
further comprising a step of forming protective films on said cavity facets in advance of said step of dividing said third oblong substrate.

5. The method of manufacturing an integrated semiconductor laser device according to claim 1, further comprising steps of:
forming first division grooves for forming said first and second side surfaces on said first oblong substrate; and
forming second division grooves for forming said third and fourth side surfaces on an opposite surface of said second oblong substrate to a second surface of said second oblong substrate, in advance of said step of dividing said third oblong substrate, wherein
said second division grooves are formed on positions deviated from positions opposed to said first division grooves, and
said second surface is bonded to said first oblong substrate.

6. The method of manufacturing an integrated semiconductor laser device according to claim 2, further comprising steps of:
preparing said first semiconductor laser device substrate by forming a plurality of said first semiconductor laser devices in a first period along said second direction,
preparing said second semiconductor laser device substrate by forming a plurality of said second semiconductor laser devices in a second period along said second direction, and
performing alignment in order to bond said first and second semiconductor laser device substrates to each other, in advance of said step of bonding said first and second semiconductor laser device substrates, wherein
said first period at a temperature in said performing alignment is larger than said second period at said temperature in case where a thermal expansion coefficient of said first semiconductor laser device substrate is smaller than that of said second semiconductor laser device substrate.

7. The method of manufacturing an integrated semiconductor laser device according to claim 2, further comprising steps of:
performing alignment in order to bond said first and second semiconductor laser device substrates to each other in advance of said step of bonding said first and second semiconductor laser device substrates, wherein
said step of preparing said first semiconductor laser device substrate includes a step of forming first alignment marks employed in said performing alignment on said first semiconductor laser device substrate in a third period along a third direction,
said step of preparing said second semiconductor laser device substrate includes a step of forming second alignment marks employed in said alignment step on said second semiconductor laser device substrate in a fourth period along said third direction, and
said third period at a temperature in said alignment step is equal to said fourth period at said temperature.

8. The method of manufacturing an integrated semiconductor laser device according to claim 2, further comprising steps of:
preparing said first semiconductor laser device substrate by forming a plurality of said first semiconductor laser devices in a fifth period along said first direction,
preparing said second semiconductor laser device substrate by forming a plurality of said second semiconductor laser devices in a sixth period along said first direction, and
performing alignment in order to bond said first and second semiconductor laser device substrates to each other,
in advance of said step of bonding said first and second semiconductor laser device substrates, wherein
said fifth period at a temperature in said performing alignment is larger than said sixth period at said temperature in case where a thermal expansion coefficient of said first semiconductor laser device substrate is smaller than that of said second semiconductor laser device substrate.

9. The method of manufacturing an integrated semiconductor laser device according to claim 1, wherein
said first oblong substrate has a substrate made of a nitride-based semiconductor, and said second oblong substrate has a substrate made of a GaAs-based semiconductor.

10. An integrated semiconductor laser device comprising:
a first semiconductor laser device formed with first electrode on a first surface and having a first side surface and a second side surface opposite to said first side surface;
a second semiconductor laser device having a second surface bonded to said first surface, a third side surface and a fourth side surface opposite to said third side surface; and
a second electrode arranged on said first semiconductor laser device and connected to said second semiconductor laser device, wherein
cavities of said first and second semiconductor laser devices extend along said first direction,
said first, second, third and fourth side surfaces extend along said first direction,
a first protruding region on said first surface is exposed between said first and third side surfaces from said second semiconductor laser device, and a second protruding region on said second surface is exposed between said second and fourth side surfaces from said first semiconductor Laser device, and
said second electrode is formed to extend from a portion between said second and first semiconductor laser devices to said first protruding region.

11. The integrated semiconductor laser device according to claim 10, wherein
a first metal wire is connected to a portion of a first electrode located on said first protruding region, and
a second metal wire is connected to a portion of said second electrode located on said first protruding region.

12. The integrated semiconductor laser device according to claim 10, wherein
said second electrode is arranged to hold an insulating layer on said first semiconductor laser device, and
said first and second electrodes are arranged in a state of being insulated from each other.

13. The integrated semiconductor laser device according to claim 12, wherein
a region connected with said first metal wire of said first electrode and a region connected with said second metal wire of said second electrode are separated from each other in said first direction on said first protruding region.

14. The integrated semiconductor laser device according to claim 10, wherein
said second semiconductor laser device is bonded to overlap on a waveguide of said first semiconductor laser device.

15. The integrated semiconductor laser device according to claim 14, wherein
said first electrode is formed to extend from a portion between said first and second semiconductor laser devices to said first protruding region.

16. The integrated semiconductor laser device according to claim 14, wherein
a waveguide of said second semiconductor laser device is formed on a position overlapped with said first semiconductor laser device.

17. The integrated semiconductor laser device according to claim 16, wherein
the waveguide of said first semiconductor laser device is formed on said first protruding region.

18. The integrated semiconductor laser device according to claim 10, wherein
a device width of said first semiconductor laser device from said first side surface to said second side surface is equal to a device width of said second semiconductor laser device from said third side surface to said fourth side surface.

19. The integrated semiconductor laser device according to claim 10, wherein
said first semiconductor laser device has a substrate made of a nitride-based semiconductor, and said second semiconductor laser device has a substrate made of a GaAs-based semiconductor.

20. An optical apparatus comprising:
an integrated semiconductor laser device including a first semiconductor laser device formed with a first electrode on a first surface and having a first side surface and a second side surface opposite to said first side surface, a second semiconductor laser device having a second surface bonded to said first surface, a third side surface and a fourth side surface opposite to said third side surface, and a second electrode arranged on said first semiconductor laser device and connected to said second semiconductor laser device; and
an optical system controlling light emitted from said integrated semiconductor laser device, wherein
a first protruding region on said first surface is exposed between said first and third side surfaces from said second semiconductor laser device, and a second protruding region on said second surface is exposed between said second and fourth side surfaces from said first semiconductor laser device,
said second electrode is formed to extend from a portion between said second and first semiconductor laser devices to said first protruding region,
cavities of said first and second semiconductor laser devices extend along said first direction, and
said first, second, third and fourth side surfaces extend along said first direction.
